(19) United States
(12) Patent Application Publication
(10) Pub. No.: US 2026/0101686 A1
(43) Pub. Date: Apr. 9, 2026

(54) METHOD FOR MANUFACTURING SEMICONDUCTOR STACK STRUCTURE WITH ULTRA THIN DIE

(71) Applicant: Nexthin Technology, George Town Grand Cayman (KY)

(72) Inventors: TZU-WEI CHIU, George Town Grand Cayman (KY); JEN-HAO YEH, George Town Grand Cayman (KY)

(21) Appl. No.: 19/001,506

(22) Filed: Dec. 25, 2024

(30) Foreign Application Priority Data
Sep. 3, 2024 (TW) 113133343

(51) Int. Cl. H01L 23/00; H01L 21/265; H01L 21/56; H01L 21/768; H01L 25/065

(52) U.S. Cl. CPC H10P 30/204; H10P 30/208; H10W 20/074; H10W 74/014; H10W 90/00; H10W 72/0198; H10W 74/10; H10W 80/312; H10W 80/327; H10W 90/297

(57) ABSTRACT

A method for manufacturing a semiconductor stack structure with ultra thin die includes manufacturing semiconductor wafers, wherein a stop layer structure formed by ion implantation is formed in the semiconductor substrate, and the conductive structures are formed to connect the dielectric stop layer and the redistribution layer of the semiconductor wafers. A bonding layer with conductive pillars is formed on the redistribution layer of another semiconductor wafer, and die sawing is performed to form multiple batches of dies. The bonding layers of a batch of dies is bonded to the exposed dielectric stop layers of the semiconductor wafers by hybrid bonding. An encapsulant covers the batch of dies, and part of the encapsulant, part of the semiconductor substrate and part of the stop layer structure of each die are removed to expose the dielectric stop layer and conductive structures of this batch of dies for bonding next batch of dies.

### FIELD OF THE INVENTION

The present invention relates to a method for manufacturing a semiconductor structure, and in particular to a method for manufacturing a semiconductor stack structure with ultra thin die.

### BACKGROUND OF THE INVENTION

With the vigorous development of electronic industry, electronic products gradually tend to be developed with multiple functions and high performance. Semiconductor technology has been widely used in the manufacturing of chipsets such as memories and central processing units. In order to achieve high integration and high speed, the size of semiconductor integrated circuits has been continuously reduced. At present, a variety of different materials and technologies have been developed to meet the above requirements for integration and speed, and a stack structure including multiple substrates has also been developed to improve the operating speed of the circuits. When the semiconductor planar packaging technology reaches its limit, the demand for miniaturization can be met through integration. The technology of stacked wafers is of great help for future technology, and has become a target that needs to be improved in the related fields at present.

### SUMMARY OF THE INVENTION

The present invention provides a method for manufacturing a semiconductor stack structure with ultra thin die, which can improve the stability of the semiconductor stack structure with ultra thin die.

In order to achieve one or part or all of the objectives or other objectives, an example of the present invention provides a method for manufacturing a semiconductor stack structure with ultra thin die, including: manufacturing a plurality of semiconductor wafers, where the manufacturing of each of the semiconductor wafers includes: providing a semiconductor substrate having an active surface and a back surface opposite to each other; forming a stop layer structure in the semiconductor substrate to divide the semiconductor substrate into a first substrate part and a second substrate part, where the first substrate part is located between the stop layer structure and the active surface, the second substrate part is located between the stop layer structure and the back surface, the stop layer structure includes a dielectric stop layer, and the manufacturing of the dielectric stop layer includes performing an ion implantation process at a depth of the semiconductor substrate and then performing a high-temperature treatment process such that the dielectric stop layer is formed in an area implanted by the ion implantation process; sequentially forming an epitaxial layer and an active layer on the active surface, and forming a plurality of conductive structures passing through the active layer, the epitaxial layer and the first substrate part, the conductive structures being connected to the dielectric stop layer; forming a redistribution layer on the active layer, the redistribution layer being electrically connected to the conductive structures; and arranging a first bonding layer on the redistribution layer; providing a carrier board, and forming a second bonding layer on the carrier board; selecting one of the semiconductor wafers as a first semiconductor wafer, and flipping the first semiconductor wafer such that the first bonding layer of the first semiconductor wafer and the second bonding layer are bonded together; removing the second substrate part and part of the stop layer structure to expose the dielectric stop layer and the conductive structures of the first semiconductor wafer; selecting another one of the semiconductor wafers as a second semiconductor wafer, and arranging a plurality of conductive pillars on the first bonding layer of the second semiconductor wafer, the conductive pillars being electrically connected to the redistribution layer; performing die sawing on the second semiconductor wafer formed with the conductive pillars as a first batch of dies and a second batch of dies to be stacked; flipping the first batch of dies such that the first bonding layer of the first batch of dies is opposite to and is bonded to the dielectric stop layer of the first semiconductor wafer by using hybrid bonding technology, where the conductive structures of the first semiconductor wafer respectively correspond to and are electrically connected to the conductive pillars of the first batch of dies; forming a first encapsulant on the dielectric stop layer of the first semiconductor wafer to cover the first batch of dies and fill between the first batch of dies; and removing part of the first encapsulant, and removing the second substrate part and part of the stop layer structure of the first batch of dies to expose the dielectric stop layer and the conductive structures of the first batch of dies.

In an example of the present invention, after exposing the dielectric stop layer and the conductive structures of the first batch of dies, the method further includes: flipping the second batch of dies such that the first bonding layer of the second batch of dies is opposite to and is bonded to the dielectric stop layer of the first batch of dies by using hybrid bonding technology, where the conductive structures of the first batch of dies respectively correspond to and are electrically connected to the conductive pillars of the second batch of dies; forming a second encapsulant on the dielectric stop layer of the first batch of dies to cover the second batch of dies and fill between the second batch of dies; and removing part of the second encapsulant, and removing the second substrate part and part of the stop layer structure of the second batch of dies to expose the dielectric stop layer and the conductive structures of the second batch of dies.

An example of the present invention provides a method for manufacturing a semiconductor stack structure with ultra thin die, including: manufacturing a plurality of the semiconductor wafers; selecting one of the semiconductor wafers as a first semiconductor wafer, and flipping the first semiconductor wafer such that the first bonding layer of the first semiconductor wafer and the second bonding layer of the carrier board are bonded together; removing the second substrate part and part of the stop layer structure of the first semiconductor wafer to expose the dielectric stop layer and the conductive structures of the first semiconductor wafer; forming a first bonding dielectric layer on the dielectric stop layer and the conductive structures of the first semiconductor wafer, a plurality of first conductive blocks passing through the first bonding dielectric layer, and the first conductive blocks being respectively electrically connected to the conductive structures; flipping the first batch of dies such that the first bonding layer of the first batch of dies is opposite to and is bonded to the first bonding dielectric layer by using hybrid bonding technology, where the first conductive blocks of the first bonding dielectric layer respectively correspond to and are electrically connected to the conductive pillars of the first batch of dies; forming a first encapsulant on the first bonding dielectric layer of the first semiconductor wafer to cover the first batch of dies and fill between the first batch of dies; and removing part of the first encapsulant, and removing the second substrate part and part of the stop layer structure of the first batch of dies to expose the dielectric stop layer and the conductive structures of the first batch of dies.

In an example of the present invention, after exposing the dielectric stop layer and the conductive structures of the first batch of dies, the method further includes: forming a second bonding dielectric layer on the first encapsulant, and the dielectric stop layer and the conductive structures of the first batch of dies, a plurality of second conductive blocks passing through the second bonding dielectric layer, and the second conductive blocks being respectively electrically connected to the conductive structures; flipping the second batch of dies such that the first bonding layer of the second batch of dies is opposite to and is bonded to the second bonding dielectric layer by using hybrid bonding technology, where the second conductive blocks respectively correspond to and are electrically connected to the conductive pillars of the second batch of dies; forming a second encapsulant on the second bonding dielectric layer to cover the second batch of dies and fill between the second batch of dies; and removing part of the second encapsulant, and removing the second substrate part and part of the stop layer structure of the second batch of dies to expose the dielectric stop layer and the conductive structures of the second batch of dies.

In an example of the present invention, the method further includes: forming a third bonding layer on the dielectric stop layer of the second batch of dies and the second encapsulant; providing a dummy carrier board, forming a fourth bonding layer on the dummy carrier board, and bonding the fourth bonding layer and the third bonding layer together; removing the carrier board, and exposing the second bonding layer; forming a plurality of slots in the second bonding layer and the first bonding layer of the first semiconductor wafer to expose the redistribution layer of the first semiconductor wafer; arranging a plurality of solder balls in the slots respectively such that the solder balls are electrically connected to the redistribution layer; and performing die sawing corresponding to positions of the second batch of dies.

An example of the present invention provides a method for manufacturing a semiconductor stack structure with ultra thin die, including: manufacturing a plurality of the semiconductor wafers; selecting one of the semiconductor wafers as a first semiconductor wafer, and flipping the first semiconductor wafer such that the first bonding layer of the first semiconductor wafer and the second bonding layer of the carrier board are bonded together; removing the second substrate part and the stop layer structure of the first semiconductor wafer to expose the first substrate part and the conductive structures of the first semiconductor wafer, where the conductive structures protrude from the first substrate part; forming a first bonding dielectric layer on the first substrate part and the conductive structures of the first semiconductor wafer; thinning the first bonding dielectric layer to expose the conductive structures of the first semiconductor wafer from a surface of the first bonding dielectric layer; flipping the first batch of dies such that the first bonding layer of the first batch of dies is opposite to and is bonded to the first bonding dielectric layer by using hybrid bonding technology, where the conductive structures exposed from the surface of the first bonding dielectric layer respectively correspond to and are electrically connected to the conductive pillars of the first batch of dies; forming a first encapsulant on the first bonding dielectric layer to cover the first batch of dies and fill between the first batch of dies; removing part of the first encapsulant, and removing the second substrate part and the stop layer structure of the first batch of dies to expose the first substrate part and the conductive structures of the first batch of dies, where the conductive structures protrude from the first substrate part; forming a second bonding dielectric layer on the first substrate part and the conductive structures of the first batch of dies; and thinning the second bonding dielectric layer to expose the conductive structures of the first batch of dies from a surface of the second bonding dielectric layer.

In an example of the present invention, after exposing the conductive structures of the first batch of dies from the surface of the second bonding dielectric layer, the method further includes: flipping the second batch of dies such that the first bonding layer of the second batch of dies is opposite to and is bonded to the second bonding dielectric layer by using hybrid bonding technology, where the conductive structures of the first batch of dies respectively correspond to and are electrically connected to the conductive pillars of the second batch of dies; forming a second encapsulant on the second bonding dielectric layer to cover the second batch of dies and fill between the second batch of dies; removing part of the second encapsulant, and removing the second substrate part and the stop layer structure of the second batch of dies to expose the first substrate part and the conductive structures of the second batch of dies, where the conductive structures protrude from the first substrate part; forming a third bonding dielectric layer on the first substrate part and the conductive structures of the second batch of dies; and thinning the third bonding dielectric layer to expose the conductive structures of the second batch of dies from a surface of the third bonding dielectric layer.

In an example of the present invention, the method further includes: providing a dummy carrier board, forming a fourth bonding layer on the dummy carrier board, and bonding the fourth bonding layer and the third bonding dielectric layer together; removing the carrier board, and exposing the second bonding layer; forming a plurality of slots in the second bonding layer and the first bonding layer of the first semiconductor wafer to expose the redistribution layer of the first semiconductor wafer; arranging a plurality of solder balls in the slots respectively such that the solder balls are electrically connected to the redistribution layer; and performing die sawing corresponding to positions of the first batch of dies or the second batch of dies.

In an example of the present invention, before forming the first bonding dielectric layer, the method further includes thinning the first substrate part of the first semiconductor wafer; and before forming the second bonding dielectric layer, the method further includes thinning the first substrate part of the first batch of dies.

In an example of the present invention, a method for manufacturing the stop layer structure includes: performing a first ion implantation process at a first depth of the semiconductor substrate; performing a second ion implantation process at a second depth of the semiconductor substrate, the second depth being different from the first depth, and elements used in the first ion implantation process being different from elements used in the second ion implantation process; and performing a high-temperature treatment process such that a deep dielectric stop layer is formed in an area implanted by the first ion implantation process and the dielectric stop layer is formed in an area implanted by the second ion implantation process, the dielectric stop layer being between the deep dielectric stop layer and the active surface.

In an example of the present invention, the elements used in the first ion implantation process and the elements used in the second ion implantation process are selected from boron, carbon, nitrogen, fluorine, phosphorus, argon and arsenic.

In an example of the present invention, the steps of removing the second substrate part and part of the stop layer structure include: performing a back grinding process to remove a part of the second substrate part from a side of the second substrate part away from the stop layer structure; removing another part of the second substrate part by a wet etching process, where an etch selectivity of the deep dielectric stop layer to the second substrate part is between 1/10 and 1/300; removing the deep dielectric stop layer by a dry etching process, where an etch selectivity of the dielectric stop layer to the deep dielectric stop layer is between ⅕ and 1/100; and performing a polishing process to remove part of the dielectric stop layer and expose the conductive structures.

In an example of the present invention, the epitaxial layer is deposited on the active surface by a metal-organic chemical vapor deposition process, and at least one active component further forms the epitaxial layer.

In an example of the present invention, a method for manufacturing the conductive structures includes: forming a plurality of through holes passing through part of the dielectric stop layer, the first substrate part, the epitaxial layer and the active layer; sequentially conformally forming an insulating layer and a barrier layer on side walls and bottom walls of the through holes; and arranging conductive materials in the through holes.

In an example of the present invention, the first bonding layer and the second bonding layer are bonded together by a fusion bonding process.

In an example of the present invention, before forming the first encapsulant to cover the first batch of dies, a back grinding process is performed on the second substrate part of the first batch of dies to remove a part of the second substrate part from a side of the second substrate part away from the stop layer structure.

In an example of the present invention, after forming the first encapsulant to cover the first batch of dies, the steps of removing part of the first encapsulant, and removing the second substrate part and part of the stop layer structure of the first batch of dies include: polishing part of the first encapsulant on the second substrate part by a chemical mechanical polishing process; removing another part of the second substrate part by a wet etching process; removing part of the stop layer structure by a dry etching process to expose the dielectric stop layer of the first batch of dies; and polishing part of the dielectric stop layer by a chemical mechanical polishing process to expose the conductive structures.

According to the present invention, by continuously stacking the dies face to face, a multilayer 3D chip structure can be formed. The stop layer structure in each batch of dies can form a robust etch stop mechanism, so wafer warpage and total thickness variation (TTV) can be avoided. Additionally, since the second substrate part, the deep dielectric stop layer and the dielectric stop layer have different etch selectivities, when the thinning process of each batch of dies is continuously performed through wet etching, dry etching and chemical mechanical polishing (CMP) processes, the process window can be increased, and the stability of the semiconductor stack structure with ultra thin die can be improved.

In order to make the aforementioned and other objectives, features and advantages of the present invention more comprehensible, examples are described in detail below with reference to the accompanying drawings.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1A to FIG. 1R show schematic cross-sectional views of a method for manufacturing a semiconductor stack structure with ultra thin die according to a first example of the present invention;

FIG. 2A and FIG. 2B show schematic views of a manufacturing flow of dies according to an example of the present invention;

FIG. 3A and FIG. 3B show schematic cross-sectional views of a method for manufacturing a stop layer structure according to an example of the present invention;

FIG. 4A to FIG. 4I show schematic cross-sectional views of part of stages of a method for manufacturing a semiconductor stack structure with ultra thin die according to a second example of the present invention; and

FIG. 5A to FIG. 5L show schematic cross-sectional views of part of stages of a method for manufacturing a semiconductor stack structure with ultra thin die according to a third example of the present invention.

### DETAILED DESCRIPTION OF PREFERRED EMBODIMENTS

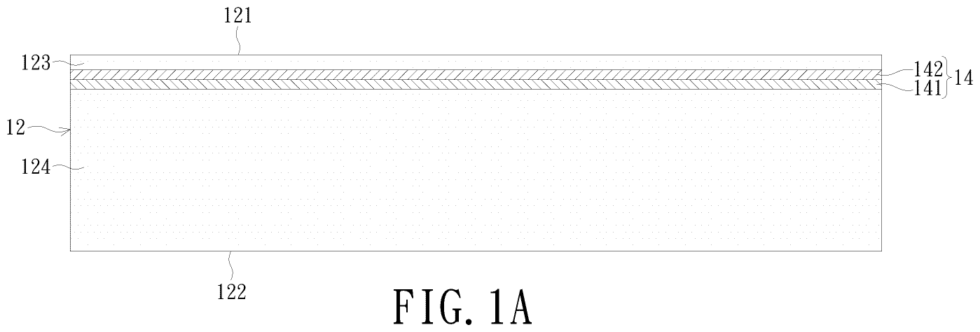

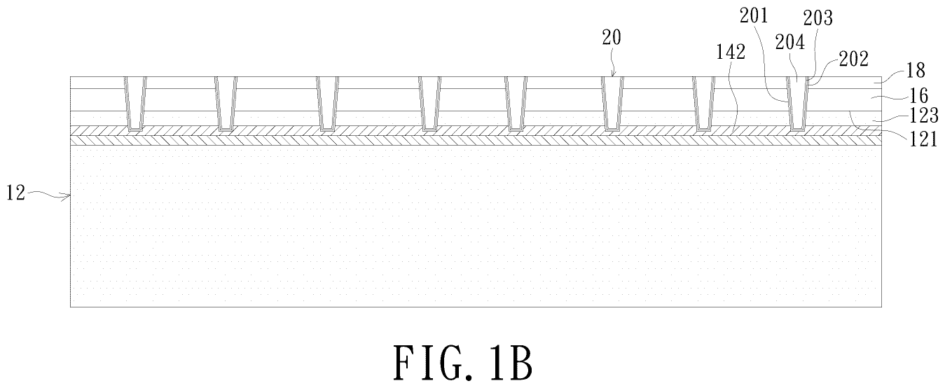

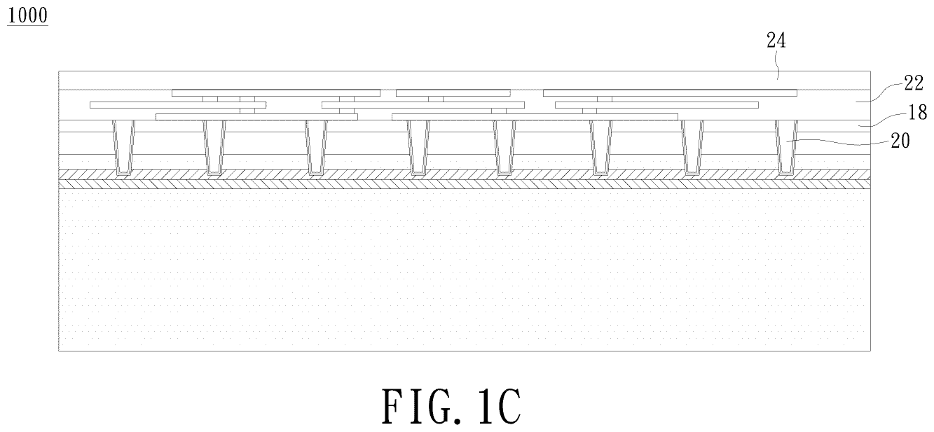

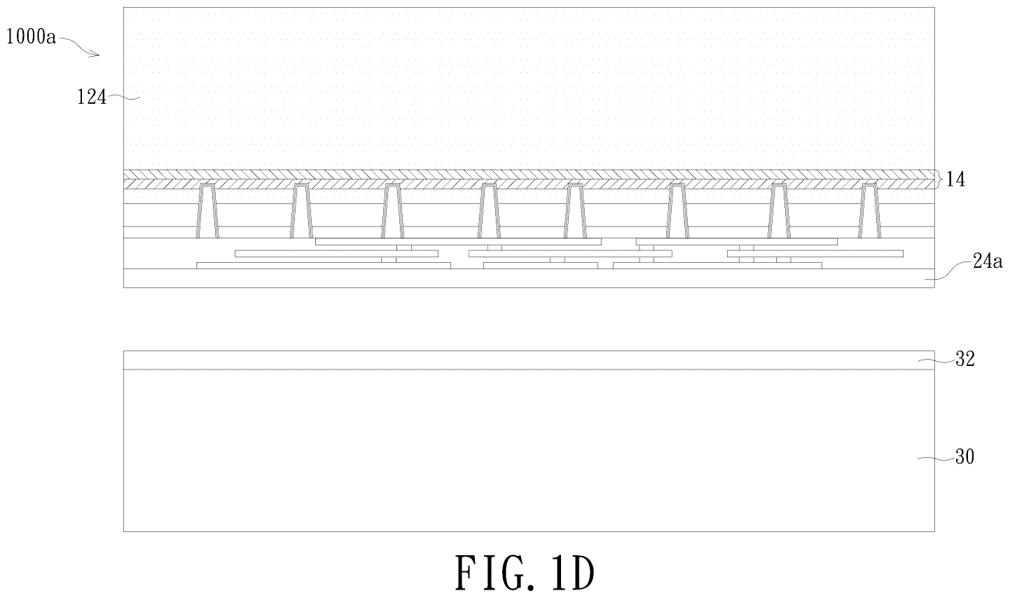

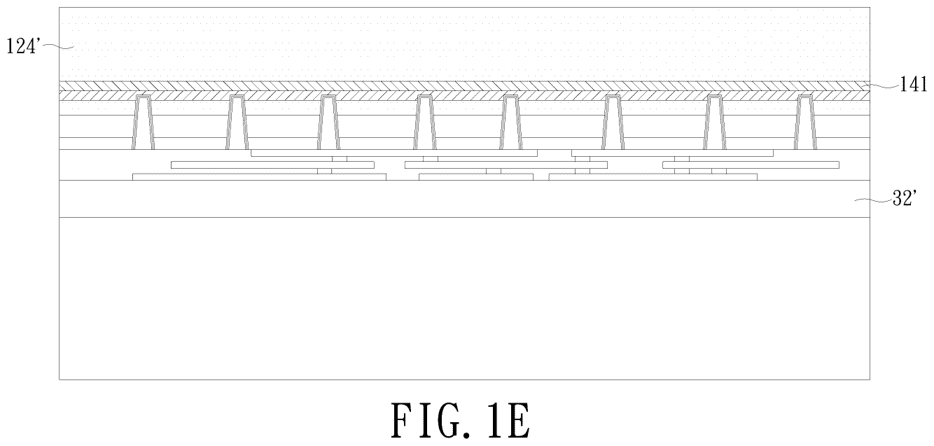

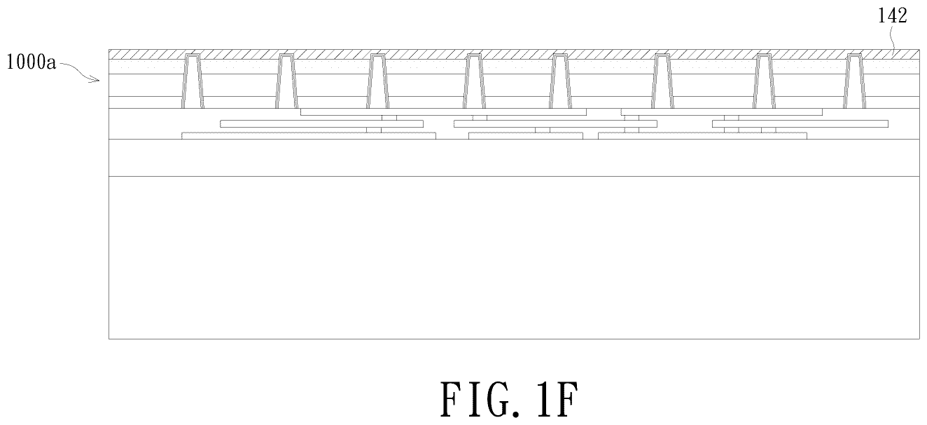

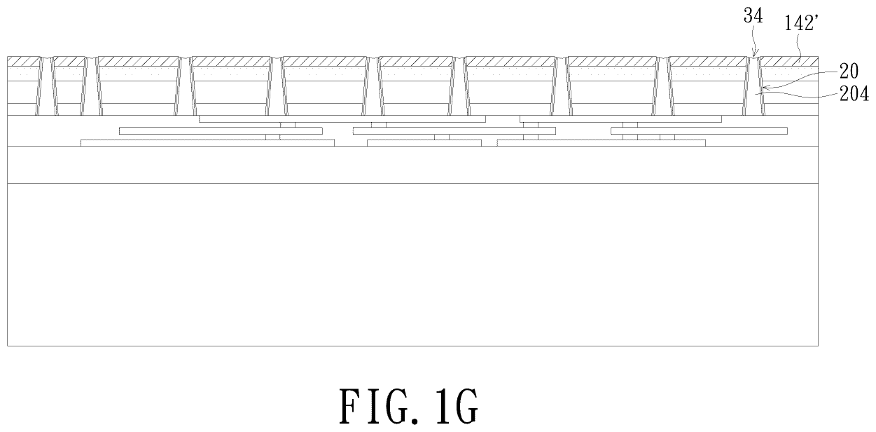

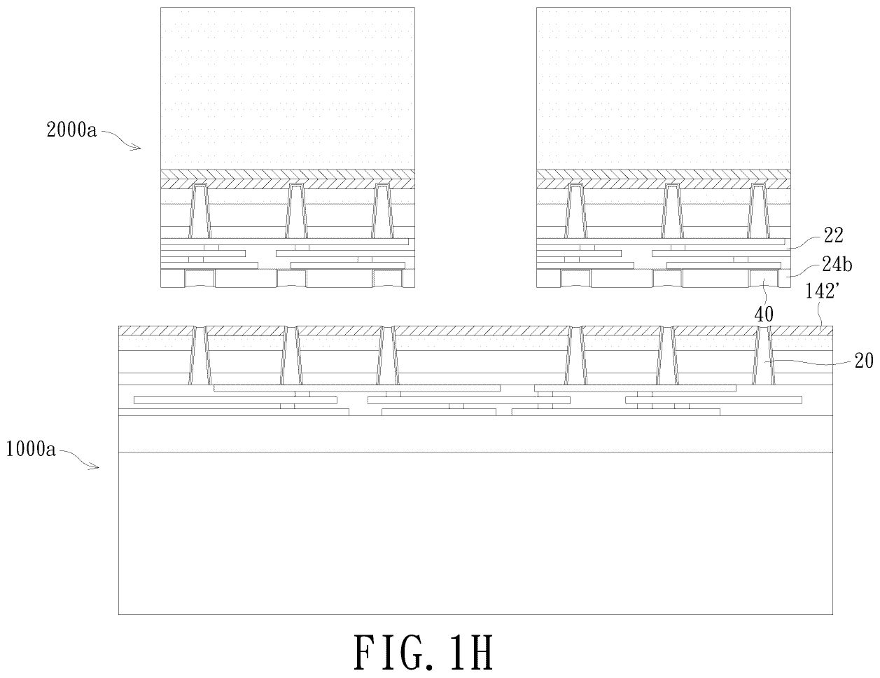

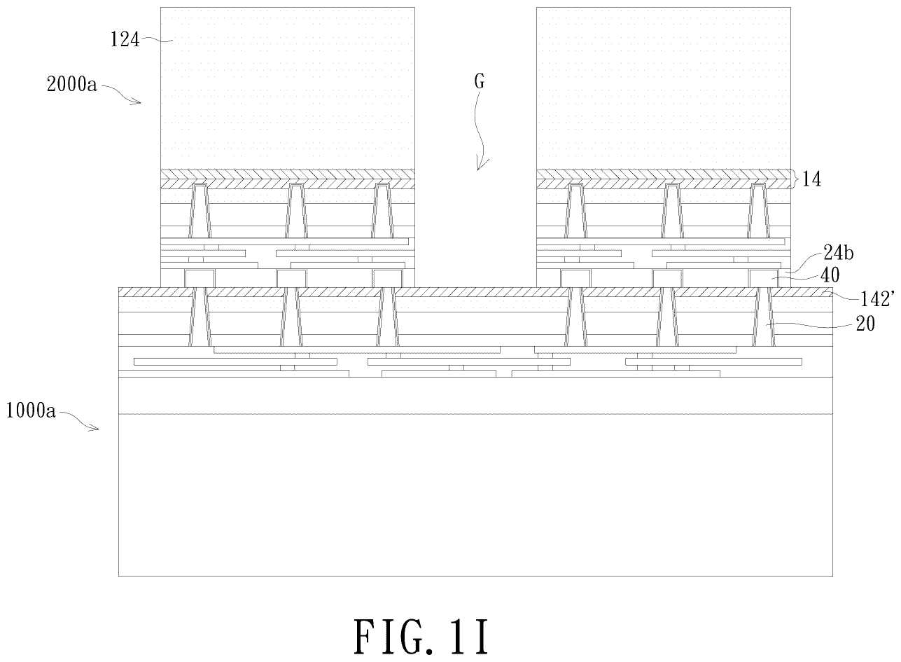

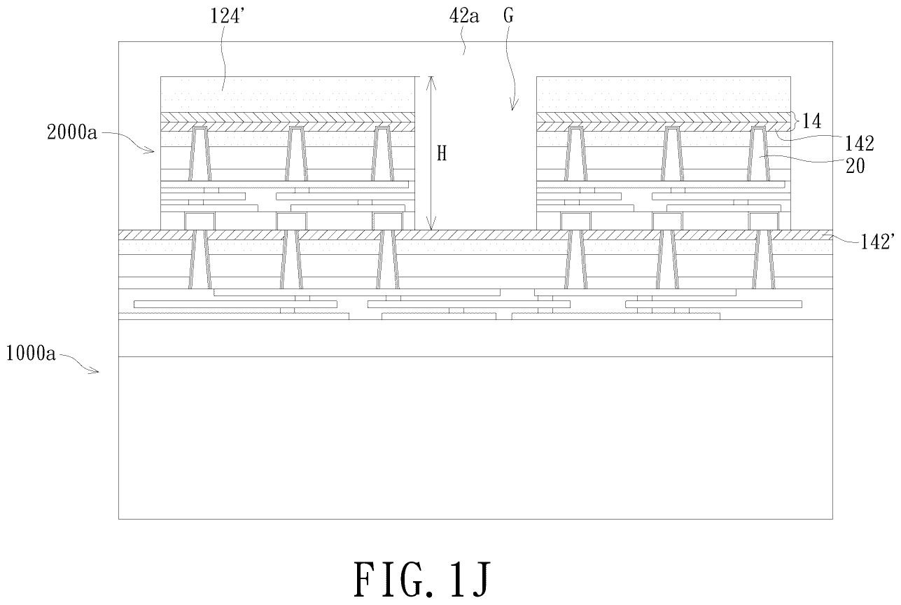

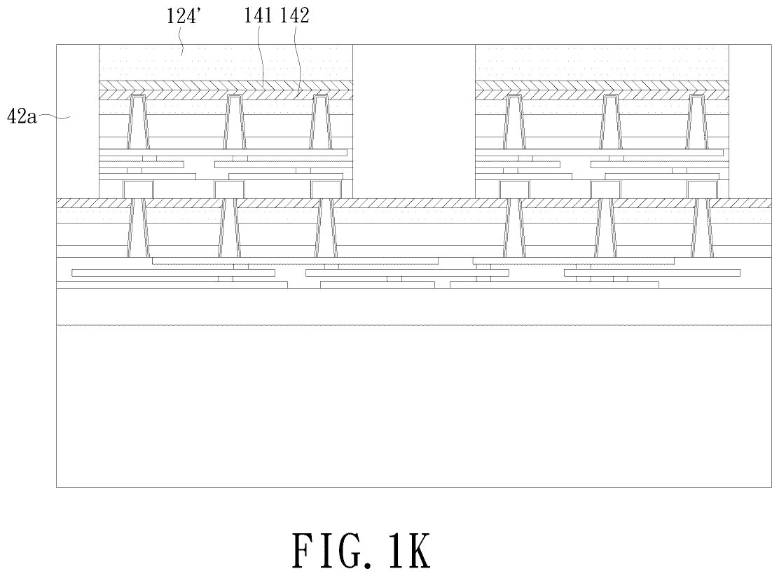

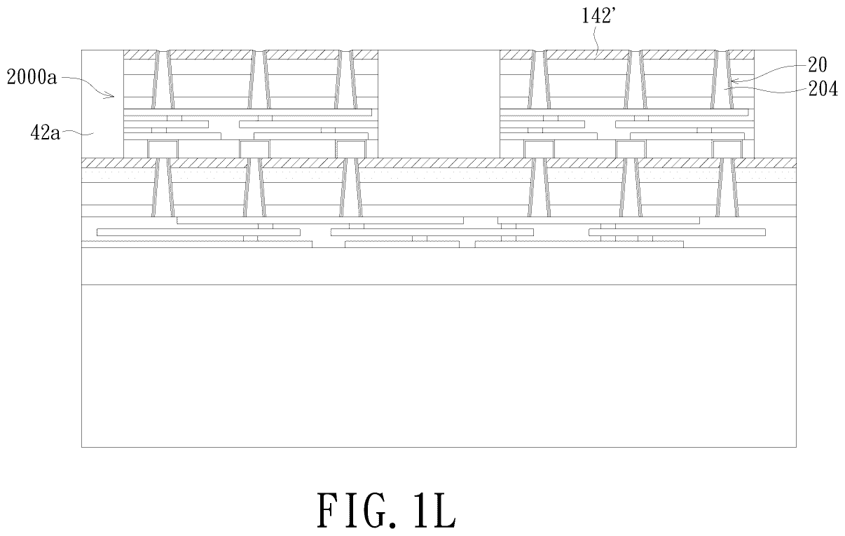

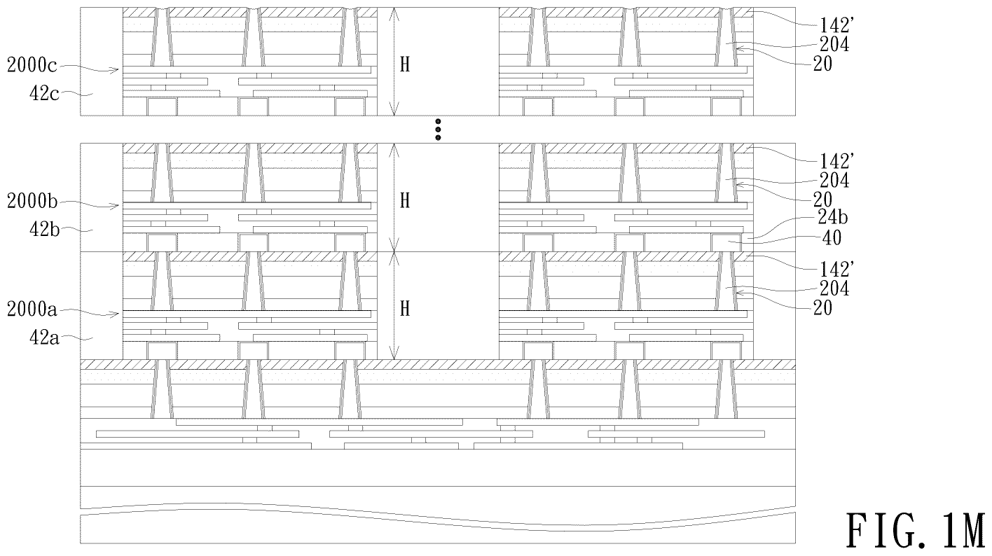

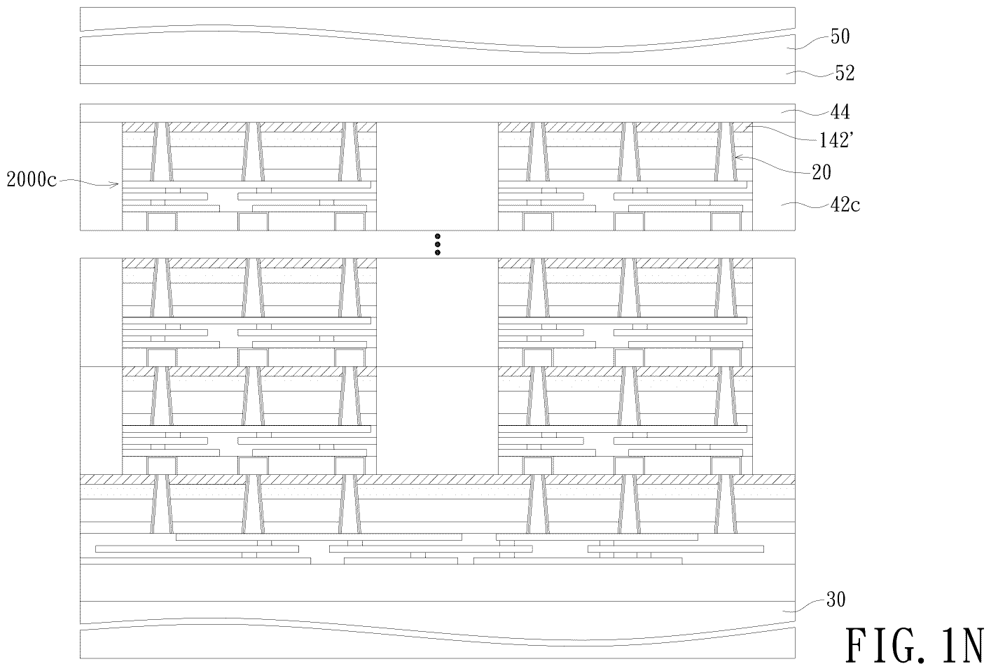

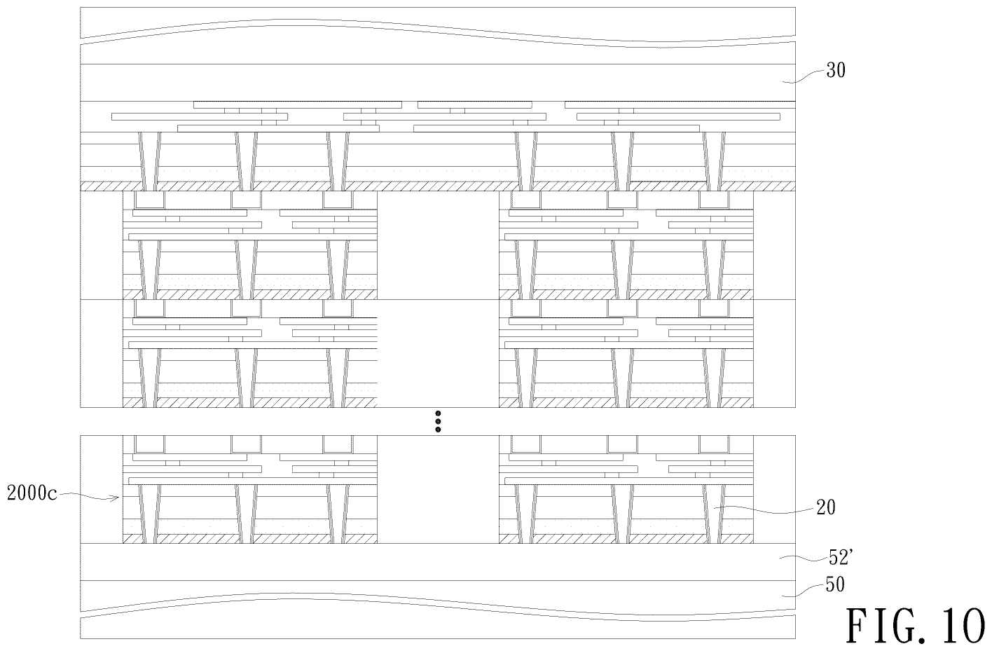

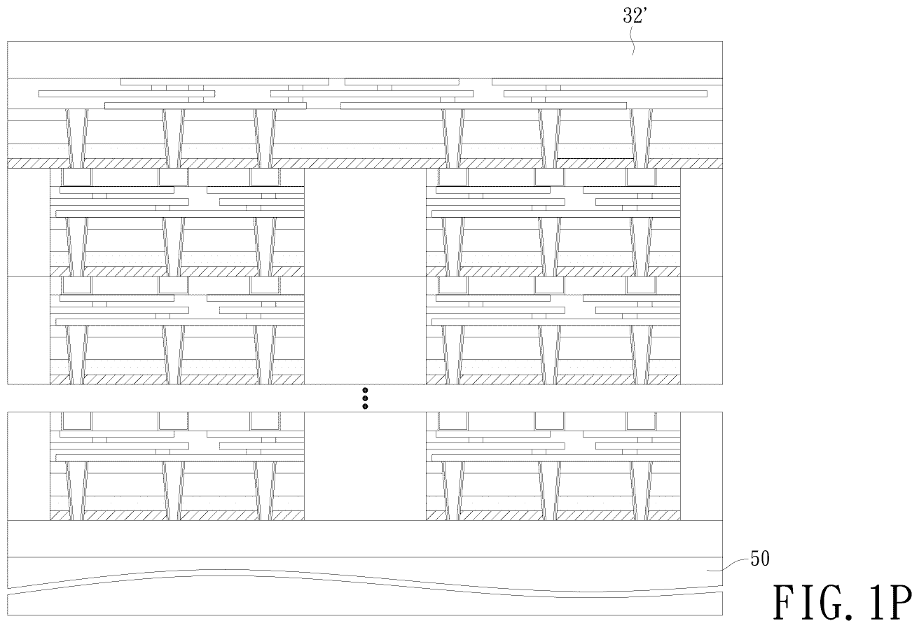

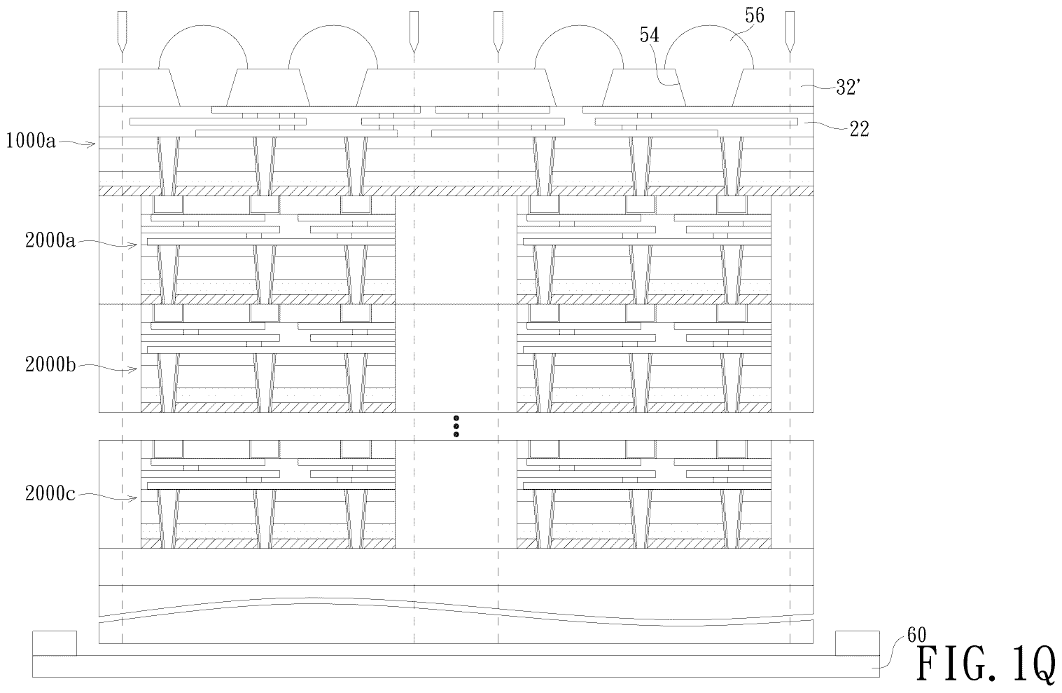

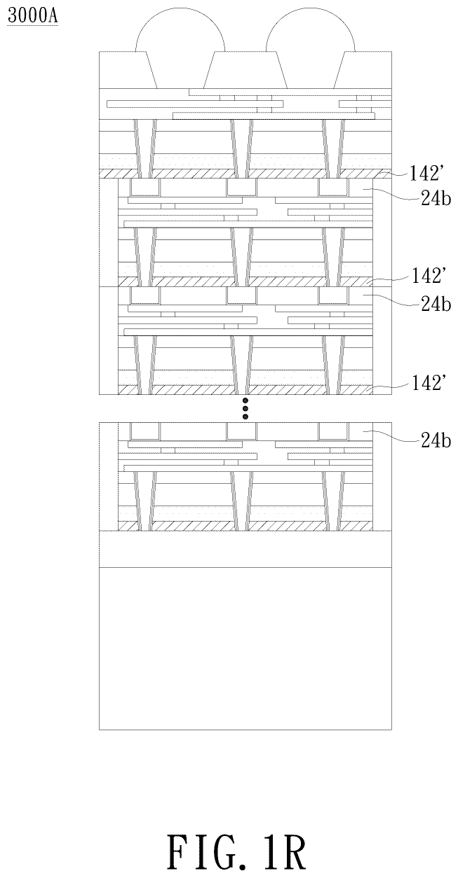

FIG. 1A to FIG. 1R show schematic cross-sectional views of a method for manufacturing a semiconductor stack structure with ultra thin die according to a first example of the present invention. First, a plurality of semiconductor wafers 1000 (denoted in FIG. 1C) are manufactured. FIG. 1A to FIG. 1C show the schematic cross-sectional views of the manufacturing of each semiconductor wafer 1000. As shown in FIG. 1A, a semiconductor substrate 12 is provided. A thickness of the semiconductor substrate 12 is, for example, 700 to 800 um, preferably 775 um. The semiconductor substrate 12 has an active surface 121 and a back surface 122 opposite to each other, and a stop layer structure 14 is formed in the semiconductor substrate 12 to divide the semiconductor substrate 12 into a first substrate part 123 and a second substrate part 124. The first substrate part 123 is located between the stop layer structure 14 and the active surface 141, and a thickness of the first substrate part 123 is between 0.05 and 2 um. The second substrate part 124 is located between the stop layer structure 14 and the back surface 122, and a thickness of the second substrate part 124 is between 30 and 775 um. In an example, the stop layer structure 14 includes a dielectric stop layer 142, and the manufacturing of the dielectric stop layer 142 includes performing an ion implantation process at a depth of the semiconductor substrate 12 and then performing a high-temperature treatment process such that the dielectric stop layer 142 is formed in an area implanted by the ion implantation process. In a preferred example, the stop layer structure 14 may include a dielectric stop layer 142 and a deep dielectric stop layer 141, and the dielectric stop layer 142 is between the deep dielectric stop layer 141 and the active surface 121, that is, the dielectric stop layer 142 is closer to the active surface 121. Thicknesses of the deep dielectric stop layer 141 and the dielectric stop layer 142 are, for example, between 50 nm and 10000 nm respectively.

Next, as shown in FIG. 1B, an epitaxial layer 16 and an active layer 18 are sequentially formed on the active surface 121, and a plurality of conductive structures 20 passing through the active layer 18, the epitaxial layer 16 and the first substrate part 123 are formed. The conductive structures 18 are connected to the dielectric stop layer 142. In an example, the epitaxial layer 16 is deposited on the active surface 121 by a metal-organic chemical vapor deposition (MOCVD) process, and a thickness of the epitaxial layer 16 is, for example, between 50 and 300 nm. In an example, the epitaxial layer 16 can prevent ions from damaging the semiconductor substrate 12 so as to prevent defects. Additionally, an active component (such as a logic or memory MOSFET, not shown) may be formed at the epitaxial layer 16. In an example, the conductive structure 20 includes, for example, a through silicon via (TSV), and the through silicon via may have a width of 0.1 to 2 um and a depth of 0.3 to 10 um. One end of the conductive structure 20 extends to the dielectric stop layer 142, and the other end of the conductive structure 20 is exposed from a surface of the active layer 18. Referring to FIG. 1B, a method for manufacturing the conductive structures 20 includes, but not limited to: first, a plurality of through holes 201 passing through part of the dielectric stop layer 142, the first substrate part 123, the epitaxial layer 18 and the active layer 18 are formed; next, an insulating layer 202 and a barrier layer 203 are sequentially conformally formed on side walls and bottom walls of the through holes 201; and then, conductive materials 204 are arranged in the through holes 201. The conductive materials 204 are, for example, copper. Additionally, the electrical connection to the conductive structures 20 described later may be understood as the electrical connection to the conductive materials 204.

As shown in FIG. 1C, a redistribution layer 22 is formed on the active layer 18, and the redistribution layer 22 is electrically connected to the conductive structures 20. In an example, a thickness of the redistribution layer 22 is, for example, about 10 um. Next, a first bonding layer 24 is arranged on the redistribution layer 22. The first bonding layer 24 is, for example, arranged on the redistribution layer 22 by a chemical vapor deposition (CVD) process. Thereby, the manufacturing of the semiconductor wafer 1000 is completed. In the subsequent process, one of the manufactured semiconductor wafers 1000 is selected as a first semiconductor wafer 1000a (denoted hereafter), and another one of the semiconductor wafers 1000 is selected as a second semiconductor wafer 1000b (denoted hereafter).

As shown in FIG. 1D, a carrier board 30 is provided. The carrier board 30 is, for example, a silicon substrate. Then, a second bonding layer 32 is formed on the carrier board 30. The second bonding layer 32 is, for example, formed by a chemical vapor deposition process. A material of the second bonding layer 32 may be the same as or different from a material of the first bonding layer 24. The materials of the first bonding layer 24 and the second bonding layer 32 are, for example, silicon dioxide (SiO₂), silicon oxynitride (SiON) or silicon nitride carbide (SiCN). Next, the first semiconductor wafer 1000a is flipped such that the first bonding layer 24a of the first semiconductor wafer 1000a and the second bonding layer 32 are bonded together. In an example, the first bonding layer 24a and the second bonding layer 32 may be bonded together by a fusion bonding process, and the fusion bonding process further includes annealing. The first bonding layer 24a and the second bonding layer 32 that are bonded together will be denoted as a fusion bonding layer 32′ in the subsequent drawings (for example, FIG. 1E).

Next, the second substrate part 124 and part of the stop layer structure 14 of the flipped first semiconductor wafer 1000a are removed to expose the dielectric stop layer 142 and the conductive structures 20 of the first semiconductor wafer 1000a. The removing steps include: performing a back grinding process on the flipped first semiconductor wafer 1000a to remove a part of the second substrate part 124 from a side of the second substrate part 124 (denoted in FIG. 1D) away from the stop layer structure 14 (denoted in FIG. 1D), as shown in FIG. 1E, so that a thickness of the remaining second substrate part 124′ is, for example, between 5 um and 50 um. Then, the remaining second substrate part 124′ is removed, for example, by a wet etching process, and the deep dielectric stop layer 141 is removed, for example, by a dry etching process, as shown in FIG. 1F, to expose the dielectric stop layer 142 of the first semiconductor wafer 1000a. Then, part of the dielectric stop layer 142 is polished by a polishing process, as shown in FIG. 1G, to expose the conductive materials 204 of the conductive structures 20. In an example, when exposing the conductive materials 204 of the conductive structures 20, the thinned dielectric stop layer 142′ still has a thickness of 50 to 500 nm left, and the thinned dielectric stop layer 142′ can be bonded with dies subsequently. The dielectric stop layer 142′ is an electrically isolatable material. In an example, as shown in FIG. 1G, based on the consideration of the hybrid bonding technology, part of the dielectric stop layer 142′ at a top end of the conductive material 204 of each conductive structure 20 and around each conductive structure 20 may optionally have a recess structure 34, and a depth of the recess structure 34 is, for example, between 3 um and 30 um. In the process of etching to remove the second substrate part 124′, an etch selectivity of the deep dielectric stop layer 141 to the second substrate part 124′ is between 1/10 and 1/300. In the process of etching to remove the deep dielectric stop layer 141, an etch selectivity of the dielectric stop layer 142 to the deep dielectric stop layer 141 is between ⅕ and 1/100.

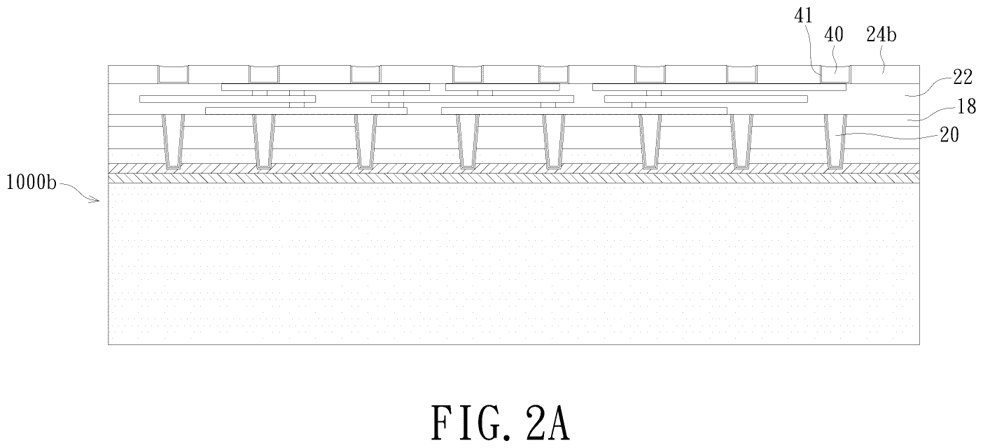

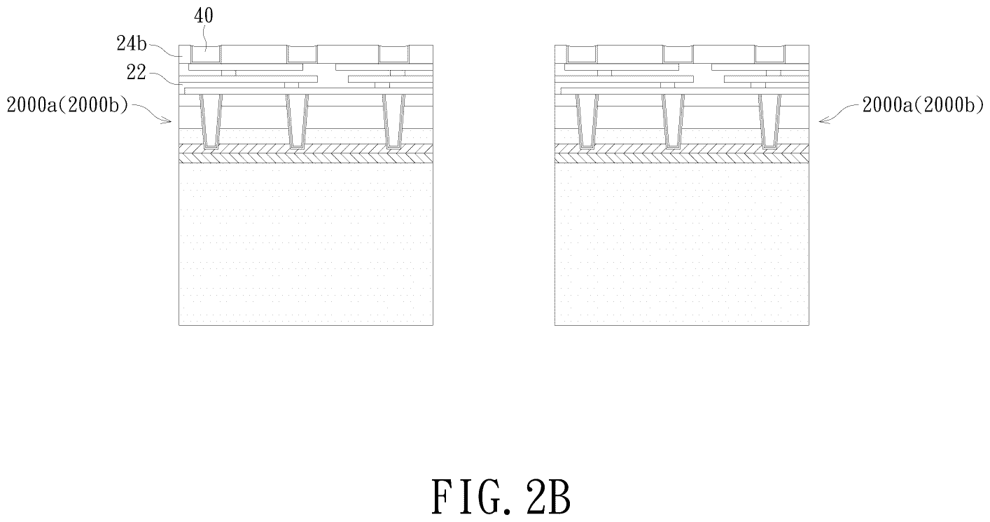

In another aspect, as for the second semiconductor wafer 1000b, FIG. 2A and FIG. 2B show schematic views of a manufacturing flow of dies according to an example of the present invention. A plurality of conductive pillars 40 are arranged on the first bonding layer 24b of the second semiconductor wafer 1000b. The conductive pillars 40 are electrically connected to the redistribution layer 22. In an example, a barrier layer 41 is formed on peripheral walls and bottoms of the conductive pillars 40. Then, die sawing is performed on the second semiconductor wafer 1000b with the conductive pillars 40 formed on the first bonding layer 24b to obtain a first batch of dies 2000a and a second batch of dies 2000b to be stacked. Thicknesses of the first batch of dies 2000a and the second batch of dies 2000b are, for example, between 50 um and 800 um. Further, with the increase of the number of stacked layers of the semiconductor stack structure with ultra thin die 3000A (denoted in FIG. 1R), a third batch of dies, a fourth batch of dies and so on are further provided.

Continuing with the above description of the method for manufacturing a semiconductor stack structure with ultra thin die according to the first example, as shown in FIG. 1H, the first batch of dies 2000a are flipped, such that the first bonding layer 24b of the first batch of dies 2000a is opposite to the dielectric stop layer 142′ of the first semiconductor wafer 1000a and the conductive pillars 40 in the first bonding layer 24b of the first batch of dies 2000a respectively correspond to the conductive structures 20 of the first semiconductor wafer 1000a. Next, the first bonding layer 24b of the first batch of dies 2000a and the dielectric stop layer 142′ of the first semiconductor wafer 1000a are bonded together by using hybrid bonding technology, as shown in FIG. 1I. The conductive pillars 40 are respectively in contact and electrically connected with the conductive structures 20. FIG. 1I shows an example where there are two first batch of dies 2000a, which is not limited thereto, and there is a gap G between the adjacent first batch of dies 2000a.

Then, a back grinding process is performed on the second substrate part 124 of the flipped first batch of dies 2000a to remove a part of the second substrate part 124 from a side of the second substrate part 124 away from the stop layer structure 14. In an example, as shown in FIG. 1J, a thickness of the remaining second substrate part 124′ is, between 5 um and 50 um, so that a distance (i.e., gap height H) between the back surface of the remaining second substrate part 124′ and the dielectric stop layer 142′ of the first semiconductor wafer 1000a is between 15 um and 70 um. Considering the problems of wafer warpage and total thickness variation (TTV), the thickness of the remaining second substrate part 124′ should not be less than 5 um, so as to avoid excessive polishing and reduced yield. Next, referring to FIG. 1J, a first encapsulant 42a is formed on the dielectric stop layer 142′ of the first semiconductor wafer 1000a to cover the first batch of dies 2000a and fill the gaps G between the first batch of dies 2000a. In an example, the first encapsulant 42a is, for example, formed by a chemical vapor deposition process, and the first encapsulant 42a includes, for example, silicon dioxide. Since the gap height H is between 15 um and 70 um, the first encapsulant 42a can easily fill the gaps G through the chemical vapor deposition process to obtain an ideal gap filling property.

Continuing with the above description, a part of the first encapsulant 42a is removed, and the remaining second substrate part 124′ and part of the stop layer structure 14 of the first batch of dies 2000a are removed to expose the dielectric stop layer 142 and the conductive structures 20 of the first batch of dies 2000a. The removing steps may sequentially include, but not limited to: part of the first encapsulant 42a above the second substrate part 124′ is polished by a chemical mechanical polishing process, as shown in FIG. 1K. The second substrate part 124′ is removed, for example, by a wet etching process while part of the first encapsulant 42a is removed; the deep dielectric stop layer 141 is removed, for example, by a dry etching process while part of the first encapsulant 42a is removed; and part of the dielectric stop layer 142 is polished by a chemical mechanical polishing process, as shown in FIG. 1L, to form the thinned dielectric stop layer 142′ and expose the conductive materials 204 of the conductive structures 20, thereby completing the stacking of the first batch of dies 2000a. In an example, in the process of etching, an etch selectivity of the deep dielectric stop layer 141 to the second substrate part 124′ is between 1/10 and 1/300; and an etch selectivity of the dielectric stop layer 142 to the deep dielectric stop layer 141 is between ⅕ and 1/100. When the second substrate part 124′ is removed by the wet etching process, wafer warpage and total thickness variation (TTV) can be avoided due to the high etch selectivity. In an example, when exposing the conductive materials 204 of the conductive structures 20, the thinned dielectric stop layer 142′ still has a thickness of 50 to 500 nm left, and the thinned dielectric stop layer 142′ can be bonded with the next batch of dies. The dielectric stop layer 142′ is an electrically isolatable material.

Then, stacking of the second batch of dies 2000b can be continued. As shown in FIG. 1M, the second batch of dies 2000b are flipped such that the first bonding layer 24b of the second batch of dies 2000b is opposite to and is bonded with the dielectric stop layer 142′ of the first batch of dies 2000a by using hybrid bonding technology. The conductive structures 20 of the first batch of dies 2000a respectively correspond to and are electrically connected to the conductive pillars 40 of the second batch of dies 2000b. Next, a second encapsulant 42b is formed on the dielectric stop layer 142′ of the first batch of dies 2000a and the first encapsulant 42a to cover the second batch of dies 2000b and fill gaps G (denoted in FIG. 1I) between the second batch of dies 2000b. Then, part of the second encapsulant 42b is removed, and the second substrate part 124′ (referring to the first batch of dies 2000a in FIG. 1J) and part of the stop layer structure 14 (referring to the first batch of dies 2000a in FIG. 1J) of the second batch of dies 2000b are removed to expose the thinned dielectric stop layer 142′ and the conductive structures 20 of the second batch of dies 2000b.

Additionally, for the next batch of dies (for example, the third batch of dies 2000c), the above steps may be repeated: the third batch of dies are bonded to the thinned dielectric stop layer 142′ of the second batch of dies 2000b by using hybrid bonding technology, the conductive structures 20 of the second batch of dies 2000b respectively correspond to and are electrically connected to the conductive pillars 40 of the third batch of dies 2000c, a third encapsulant 42c is formed on the thinned dielectric stop layer 142′ of the second batch of dies 2000b to cover the third batch of dies 2000c and fill gaps G (denoted in FIG. 1I) between the third batch of dies 2000c, the thinned dielectric stop layer 142′ and the conductive materials 204 of the conductive structures 20 of the third batch of dies 2000c are exposed through removing and other steps, and so on. These steps are repeated many times to complete the stacking of a predetermined number of layers of dies.

Then, as shown in FIG. 1N, a third bonding layer 44 is formed on the exposed dielectric stop layer 142′ and the encapsulant (for example, the third encapsulant 42c covering the third batch of dies 2000c) of the top dies (for example, the third batch of dies 2000c) farthest from the carrier board 30. On the other hand, a dummy carrier board 50 is formed, and a fourth bonding layer 52 is formed on the dummy carrier board 50. Next, the fourth bonding layer 52 and the third bonding layer 44 are bonded together. In an example, the third bonding layer 44 and the fourth bonding layer 52 may be bonded together by a fusion bonding process, and the third bonding layer 44 and the fourth bonding layer 52 that are bonded together will be denoted as a fusion bonding layer 52′ in the subsequent drawings (for example, FIG. 1O). In the top dies (for example, the third batch of dies 2000c), the conductive structures 20 (for example, TSVs) are still formed, which is based on the consideration of heat dissipation. Additionally, the combination of the dummy carrier board 50 and the top dies (for example, the third batch of dies 2000c) can ensure a thickness of the whole stack structure to be about 700 um, so as to maintain the overall structural strength.

After bonding the dummy carrier board 50, as shown in FIG. 1O, the whole stack structure is flipped upside down, such that the dummy carrier board 50 is located at the bottom and the carrier board 30 is located at the top. Next, the carrier board 30 located at the top is removed, as shown in FIG. 1P to expose the fusion bonding layer 32′. In an example, the carrier board 30 may be removed by a wet etching process or a stripping technology. Next, as shown in FIG. 1Q, a plurality of slots 54 are formed in the fusion bonding layer 32′ to expose the redistribution layer 22 of the first semiconductor wafer 1000a. In an example, the slots 54 may be formed by a photolithography/etching process. Then, a plurality of solder balls 56 are respectively arranged in the slots 54 such that the solder balls 56 are electrically connected to the redistribution layer 22. In an example, the solder balls 56 may be formed by sputtering, photolithography, electrochemical plating (ECP) and wet etching processes. Finally, die sawing is performed corresponding to positions of the first batch of dies 2000a/second batch of dies 2000b/third batch of dies 2000c stacked with each other to complete the semiconductor stack structure with ultra thin die 3000A shown in FIG. 1R. As shown in FIG. 1Q, the stack structure may be mounted on a framework 60, and then subjected to die sawing by plasma cutting or mechanical cutting.

The semiconductor substrate 12 is, for example, a silicon substrate, an epitaxial silicon substrate, a silicon germanium substrate, a silicon carbide substrate or a silicon on insulation (SOI) substrate.

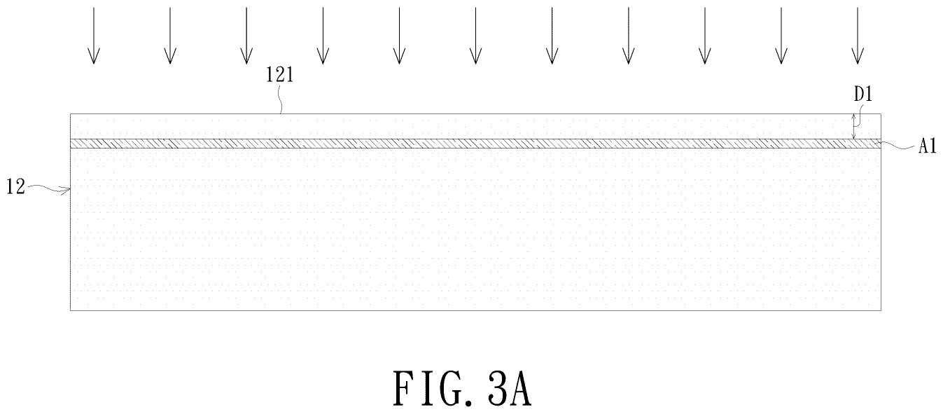

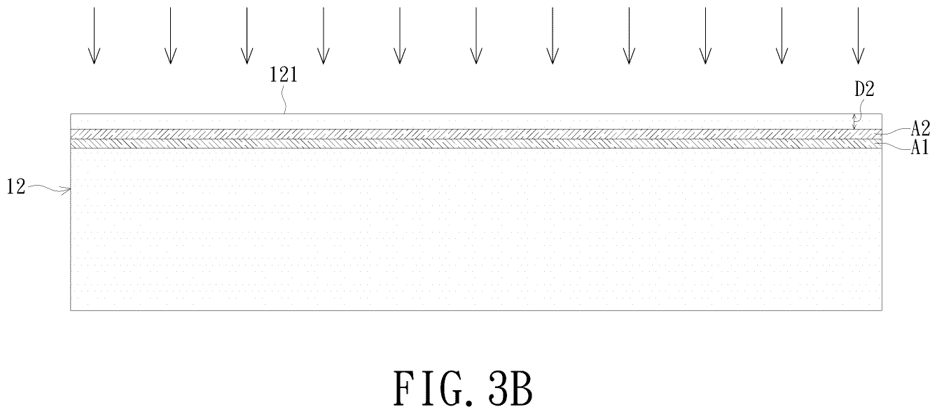

In an example, FIG. 3A and FIG. 3B show schematic cross-sectional views of a method for manufacturing the stop layer structure according to an example of the present invention. As shown in FIG. 3A, a first ion implantation process is performed at a first depth D1 of the semiconductor substrate 12. The first depth D1 of an area A1 implanted by the first ion implantation process is a depth, for example, of about 1 to 5 um, from the active surface 121. Next, as shown in FIG. 3B, a second ion implantation process is performed on the semiconductor substrate 12. The second depth D2 is different from the first depth D1. The second depth D2 is smaller than the first depth D1, that is, an area A2 implanted by the second ion implantation process is closer to the active surface 121. Elements used in the first ion implantation process and elements used in the second ion implantation process are selected from boron, carbon, nitrogen, fluorine, phosphorus, argon and arsenic, and the elements used in the first ion implantation process are different from the elements used in the second ion implantation process. Next, a high-temperature treatment process is performed, such that the deep dielectric stop layer 141 (as shown in FIG. 1A) is formed in the area A1 implanted by the first ion implantation process and the dielectric stop layer 142 (as shown in FIG. 1A) is formed in the area A2 implanted by the second ion implantation process.

In the method for manufacturing a semiconductor stack structure with ultra thin die according to the first example of the present invention, the conductive structures 20 (for example, TSVs) shown in FIG. 1B are formed after the contact process of the middle-end-of-line (MEOL) of the semiconductor or after the mid-level interconnect (MLI) process of the front-end-of-line (FEOL). It can be understood that the middle-end-of-line usually covers the process related to manufacturing of connection structures (also called contacts or plugs) connected to the conductive member (or conductive region) of the IC device. The back-end-of-line (BEOL) usually covers processes related to manufacturing of multilayer interconnect structures electrically connected to the connection structures by means of IC devices manufactured by FEOL and MEOL. Additionally, when removing a part of the second substrate part 124 from a side of the second substrate part 124 away from the stop layer structure 14 by a back grinding process, as shown in FIG. 1E, the remaining second substrate part 124′ (with a thickness, for example, between 5 um and 50 um) can solve the problem of wafer warpage. When removing the remaining second substrate part 124′ by a wet etching process subsequently, the second substrate part 124′ can be removed significantly, and moreover, the deep dielectric stop layer 141 can effectively delay chemical etching without further infiltration. Additionally, due to the significant etch selectivity between the deep dielectric stop layer 141 and the dielectric stop layer 142, the dry etching process will only remove the deep dielectric stop layer 141 and stop at the dielectric stop layer 142.

Further, in the method for manufacturing a semiconductor stack structure with ultra thin die according to the first example of the present invention, as shown in FIG. 1H, the first batch of dies 2000a and the first semiconductor wafer 1000a are stacked in a face-to-face and chip-on-wafer (CoW) manner. The advantage of the CoW is that chip probing (CP) can be performed first to obtain known good dies passing the electrical function test, thereby ensuring high yield production. Additionally, as shown in FIG. 1M, since the second substrate part 124 of each batch of dies (for example, first batch of dies 2000a/second batch of dies 2000b/third batch of dies 2000c) has been partially polished by a back grinding process such that the gap height H is between 15 um and 70 um, it is easy to implement gap filling of the encapsulant by a chemical vapor deposition process to obtain an ideal gap filling property.

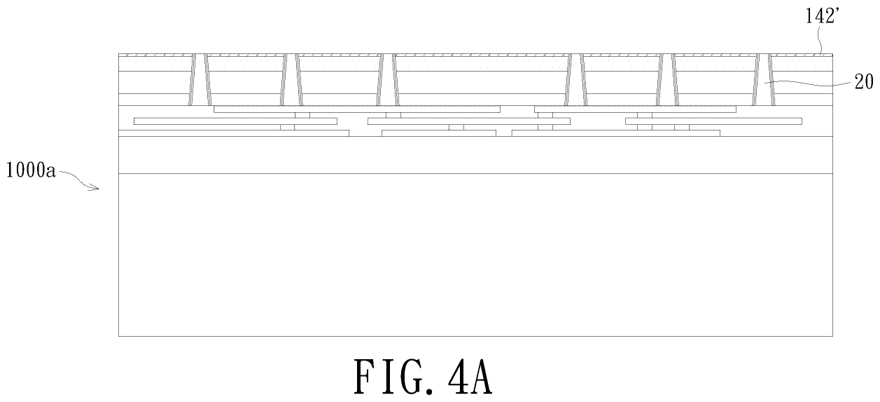

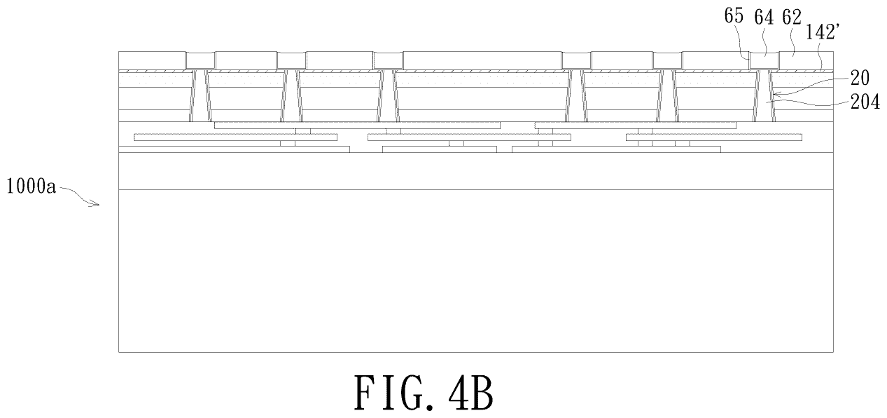

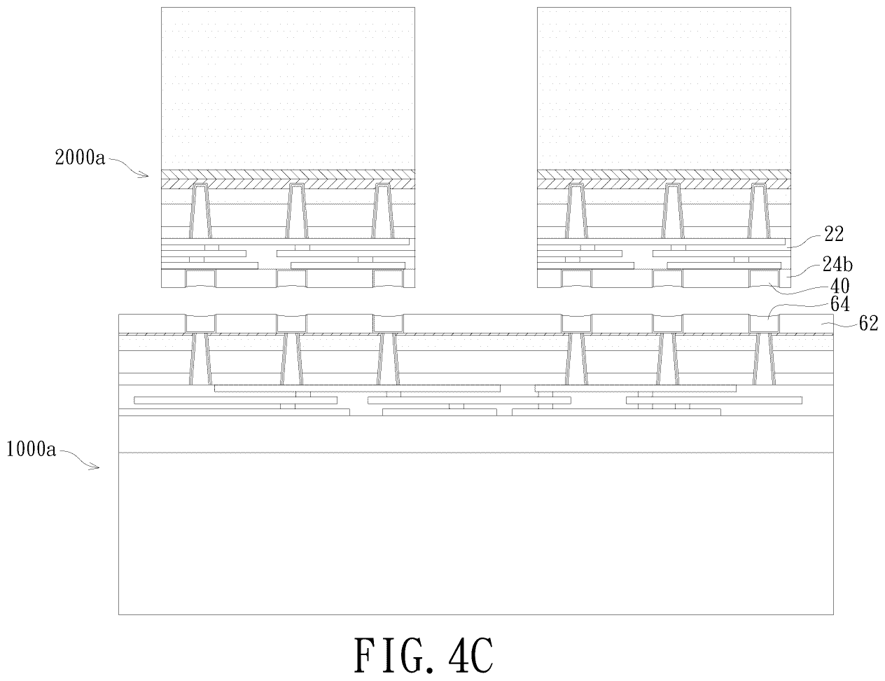

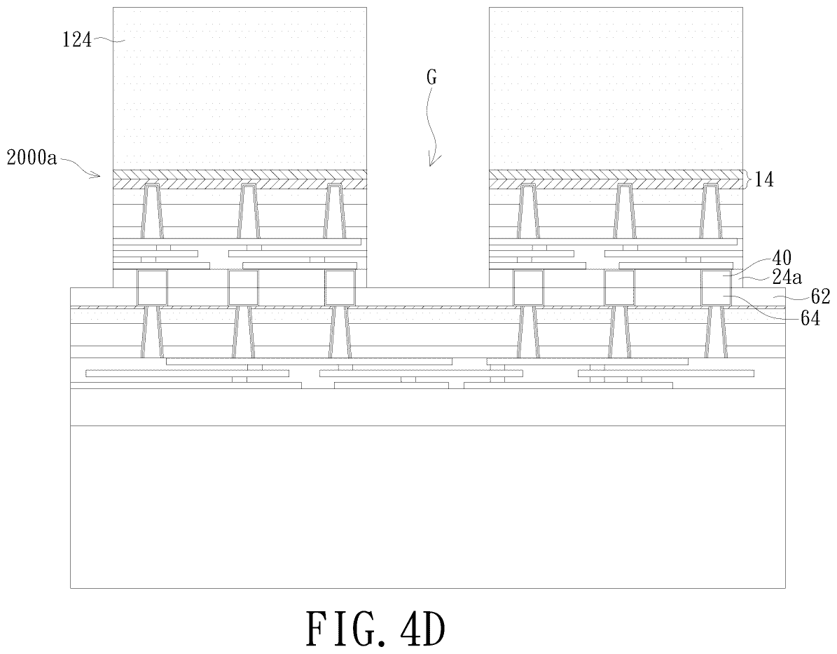

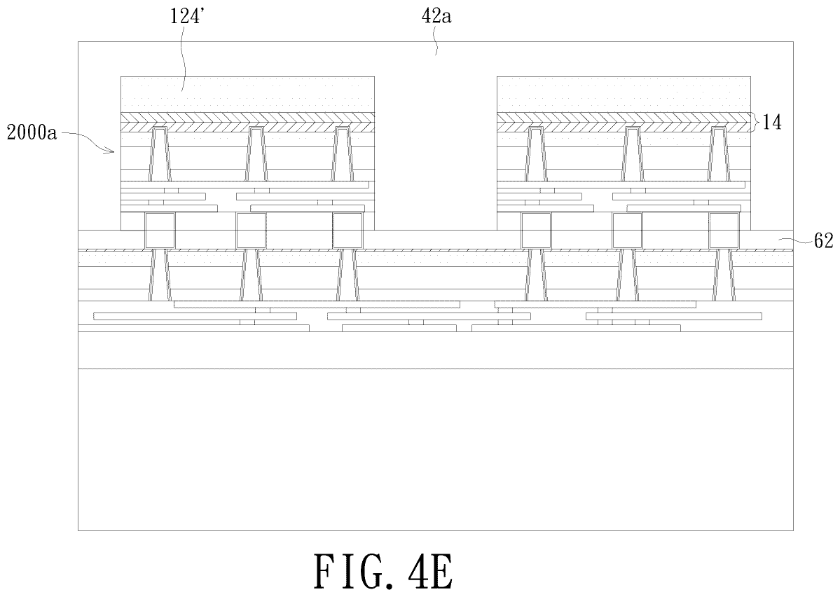

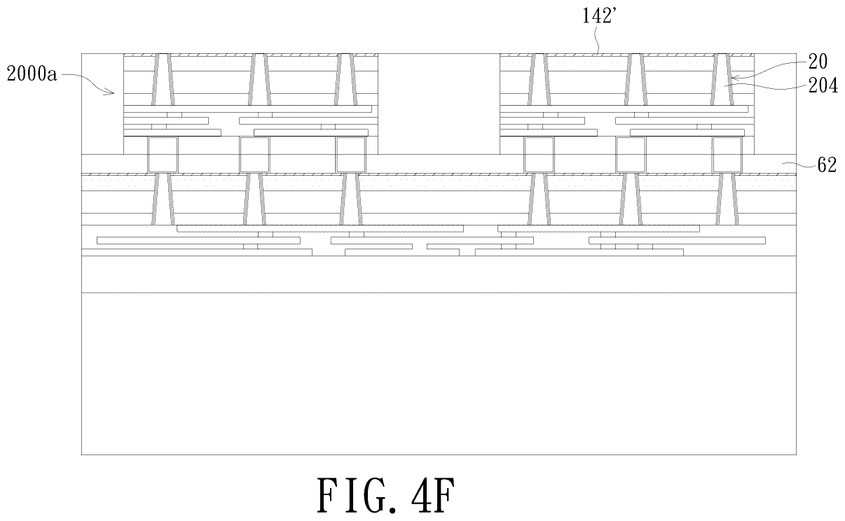

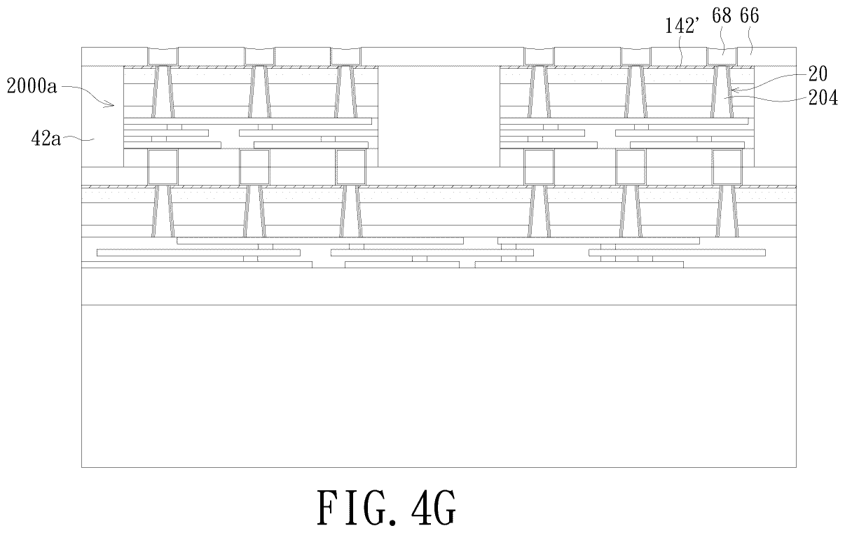

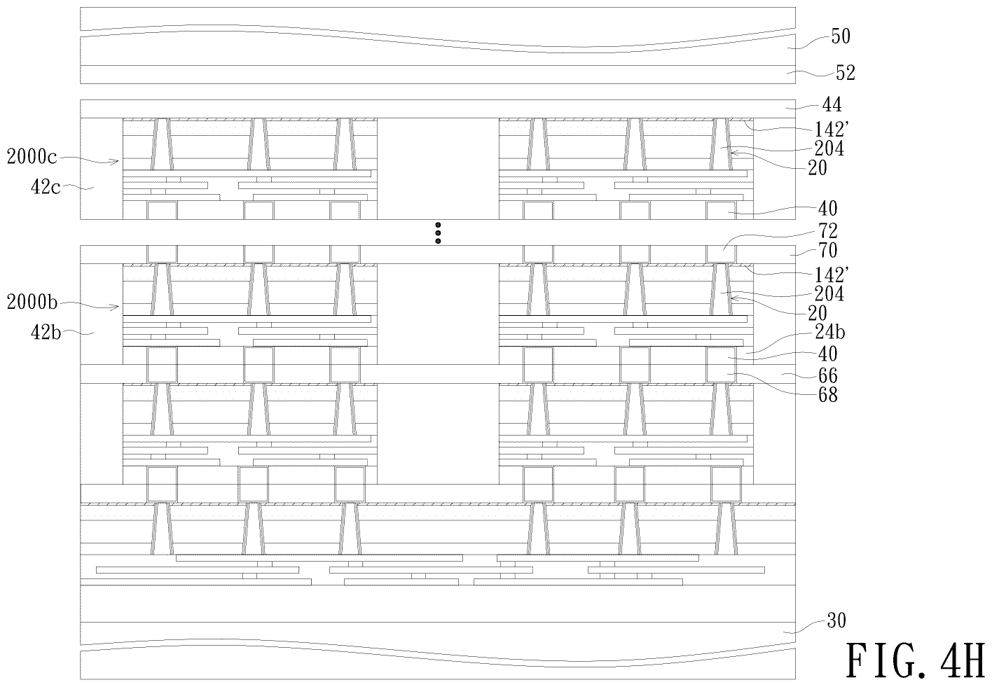

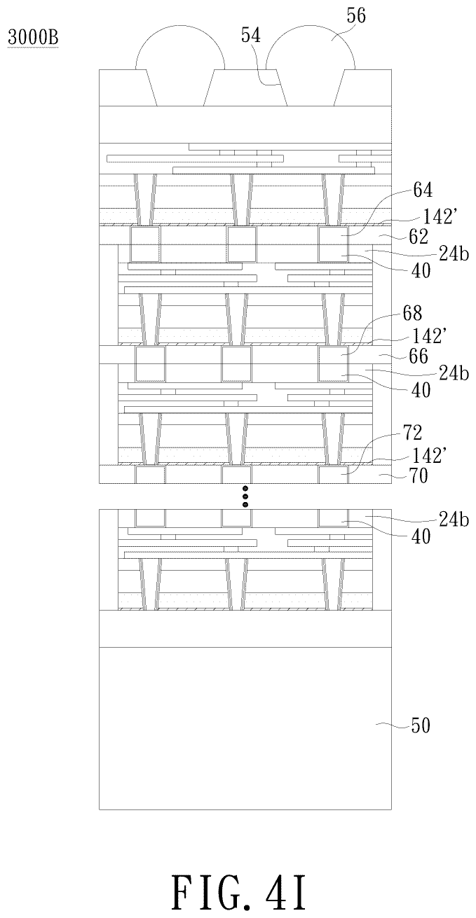

FIG. 4A to FIG. 4I show schematic cross-sectional views of part of stages of a method for manufacturing a semiconductor stack structure with ultra thin die according to a second example of the present invention. The previous stage process of the method for manufacturing a semiconductor stack structure with ultra thin die according to the second example is shown in FIG. 1A to FIG. 1G, and will not be repeated here. As shown in FIG. 4A (corresponding to FIG. 1G), the conductive structures 20 are exposed from a surface of the thinned dielectric stop layer 142′ of the first semiconductor wafer 1000a. Next, as shown in FIG. 4B, a first bonding dielectric layer 62 is formed on the thinned dielectric stop layer 142′ and the conductive structures 20 of the first semiconductor wafer 1000a. A plurality of first conductive blocks 64 run through the first bonding dielectric layer 62, and the first conductive blocks 64 are respectively electrically connected to the conductive materials 204 of the conductive structures 20. In an example, a barrier layer 65 is formed on peripheral walls and bottoms of the first conductive blocks 64. In an example, the first conductive blocks 64 are, for example, copper blocks, and the first bonding dielectric layer 62 and the first conductive blocks 64 are formed, for example, by chemical vapor deposition, photolithography, etching, sputtering, electrochemical plating and chemical mechanical polishing processes, to serve as a bonding layer to be hybrid-bonded with the dies.

Next, the first batch of dies 2000a, the second batch of dies 2000b, the third batch of dies 2000c and the subsequent more batches of dies to be stacked are provided. For the manufacturing of each batch of dies, reference may be made to FIG. 2A and FIG. 2B, and details will not be repeated here. As shown in FIG. 4C, the first batch of dies 2000a are flipped such that the first bonding layer 24b of the first batch of dies 2000a is opposite to the first bonding dielectric layer 62 on the first semiconductor wafer 1000a and the conductive pillars 40 in the first bonding layer 24b of the first batch of dies 2000a respectively correspond to the first conductive blocks 64 in the first bonding dielectric layer 62. Next, the first bonding layer 24b of the first batch of dies 2000a and the first bonding dielectric layer 62 are bonded together by using hybrid bonding technology, as shown in FIG. 4D. The first conductive blocks 64 in the first bonding dielectric layer 62 respectively correspond to and are electrically connected to the conductive pillars 40 of the first batch of dies 2000a. FIG. 4D shows an example where there are two first batch of dies 2000a, which is not limited thereto, and there is a gap G between the adjacent first batch of dies 2000a.

Then, a back grinding process is performed on the second substrate part 124 of the flipped first batch of dies 2000a to remove a part of the second substrate part 124 from a side of the second substrate part 124 away from the stop layer structure 14 to obtain the remaining (or thinned) second substrate part 124′, as shown in FIG. 4E. Next, a first encapsulant 42a is formed on the first bonding dielectric layer 62 to cover the first batch of dies 2000a and fill gaps G (denoted in FIG. 4D) between the first batch of dies 2000a. The effects that the remaining second substrate part 124′ can achieve and the method for forming the first encapsulant 42a have been disclosed in the first example and will not be repeated here.

Next, part of the first encapsulant 42a, and the remaining second substrate part 124′ and part of the stop layer structure 14 of the first batch of dies 2000a are removed, as shown in FIG. 4F, to expose the dielectric stop layer 142′ and the conductive materials 204 of the conductive structures 20 of the first batch of dies 2000a. The removing steps has been disclosed in the first example and will not be repeated here. Next, different from the first example, as shown in FIG. 4G, first, a second bonding dielectric layer 66 is formed on the first encapsulant 42a, and the dielectric stop layer 142′ and the conductive structures 20 of the first batch of dies 2000a. A plurality of second conductive blocks 68 run through the second bonding dielectric layer 66, and the second conductive blocks 68 are respectively electrically connected to the conductive materials 204 of the first batch of dies 2000a. Then, stacking of the next batch of dies is performed.

As shown in FIG. 4H, the second batch of dies 2000b are flipped such that the first bonding layer 24b of the second batch of dies 2000b is opposite to and is bonded to the second bonding dielectric layer 66 by using hybrid bonding technology. The conductive pillars 40 of the second batch of dies 2000b respectively correspond to and are electrically connected to the second conductive blocks 68 in the second bonding dielectric layer 66. Next, a second encapsulant 42b is formed on the second bonding dielectric layer 66 to cover the second batch of dies 2000b. Then, part of the second encapsulant 42b is removed, and the second substrate part 124 (referring to the first batch of dies 2000a in FIG. 4D) and part of the stop layer structure 14 (referring to the first batch of dies 2000a in FIG. 4D) of the second batch of dies 2000b are removed to expose the thinned dielectric stop layer 142′ and the conductive materials 204 of the conductive structures 20 of the second batch of dies 2000b. A third bonding dielectric layer 70 and third conductive blocks 72 are formed on the second encapsulant 42b, and the dielectric stop layer 142′ and the conductive materials 204 of the second batch of dies 2000b. The second conductive blocks 72 are respectively electrically connected to the conductive materials 204 of the second batch of dies 2000b.

Additionally, for the next batch of dies (for example, the third batch of dies 2000c), the above steps may be repeated: the third batch of dies are bonded to the third bonding dielectric layer 70 by using hybrid bonding technology, the conductive pillars 40 of the third batch of dies 2000c respectively correspond to and are electrically connected to the third conductive blocks 72 in the third bonding dielectric layer 70, a third encapsulant 42c is formed on the third bonding dielectric layer 70 to cover the third batch of dies 2000c, the thinned dielectric stop layer 142′ and the conductive materials 204 of the third batch of dies 2000c are exposed through removing and other steps, and so on. These steps are repeated many times to complete the stacking of a predetermined number of layers of dies. Then, a third bonding layer 44 is formed on the exposed dielectric stop layer 142′ and the encapsulant (for example, the third encapsulant 42 covering the third batch of dies 2000c) of the top dies (for example, the third batch of dies 2000c) farthest from the carrier board 30, so as to be bonded to the fourth bonding layer 52 of the dummy carrier board 50.

Continuing with the above description, after the bonding to the dummy carrier board 50, the subsequent processes of removing of the carrier board 30, forming of the slots 54, arranging of the solder balls 56 and die sawing are further performed, which have been disclosed in the first example and will not be repeated here. FIG. 4I shows the semiconductor stack structure with ultra thin die 3000B after die sawing, which is different from the semiconductor stack structure with ultra thin die 3000A shown in FIG. 1R in the first example mainly in that: the bonding dielectric layer (for example, the first bonding dielectric layer 62/second bonding dielectric layer 66/third bonding dielectric layer 70) is formed on the exposed stop layer structure (for example, the dielectric stop layer 142′) of the semiconductor stack structure with ultra thin die 3000B, and the conductive blocks (for example, the first conductive blocks 64/second conductive blocks 68/third conductive blocks 72) are formed in the bonding dielectric layer, so that the first bonding layer 24b of each batch of dies is hybrid-bonded to the first bonding dielectric layer 62/second bonding dielectric layer 66/third bonding dielectric layer 70, rather than that the first bonding layer 24b of each batch of dies is directly hybrid-bonded to the exposed stop layer structure (for example, the dielectric stop layer 142′) as shown in the semiconductor stack structure with ultra thin die 3000A in FIG. 1R.

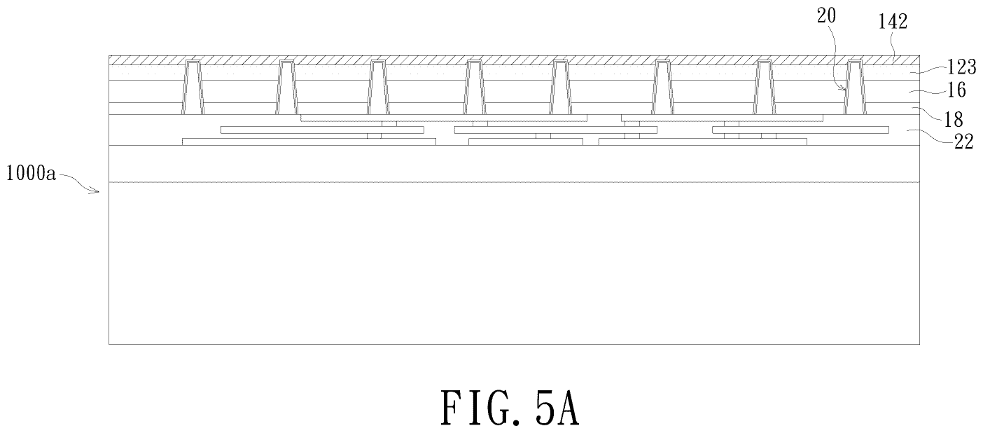

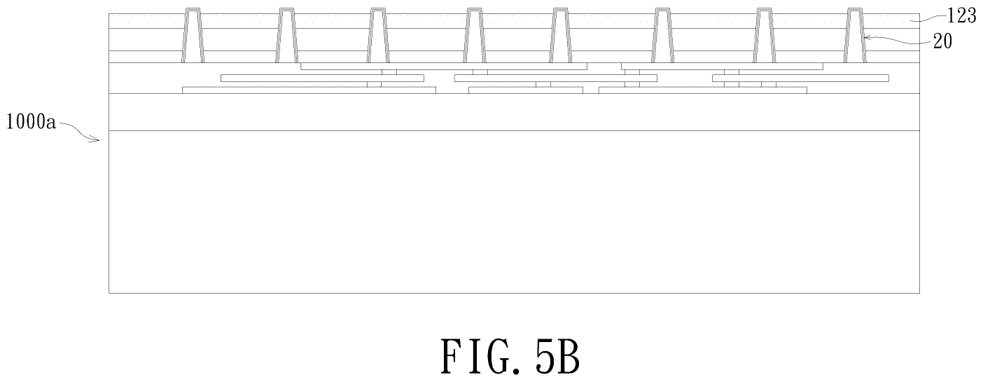

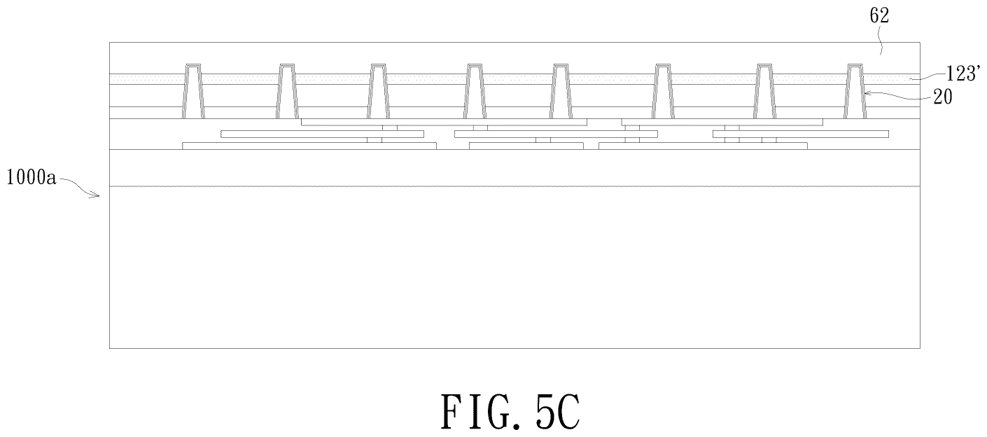

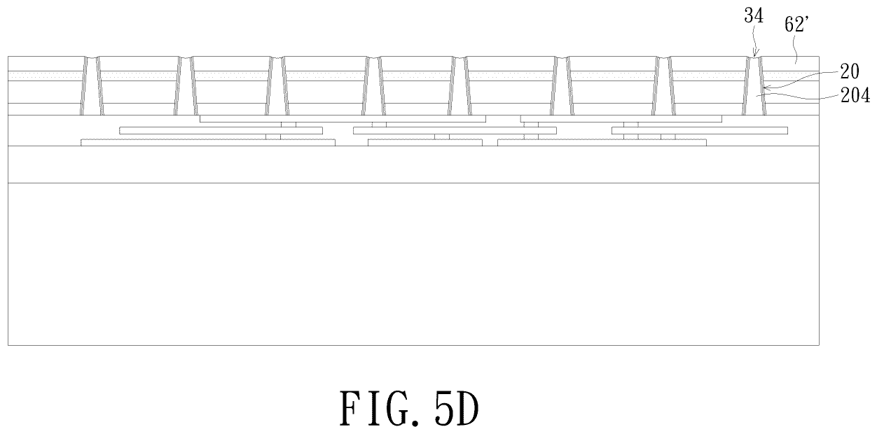

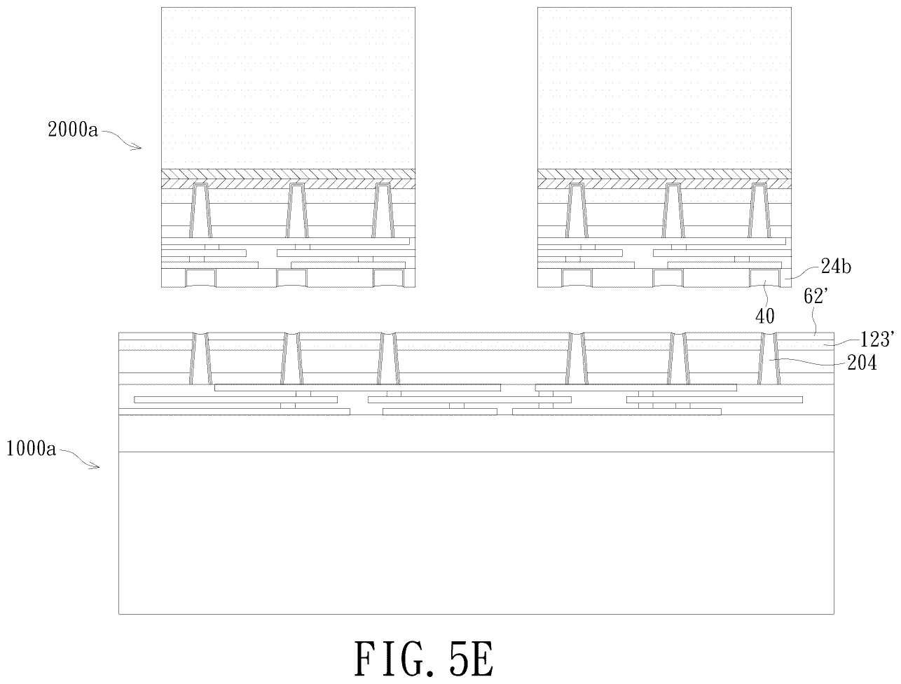

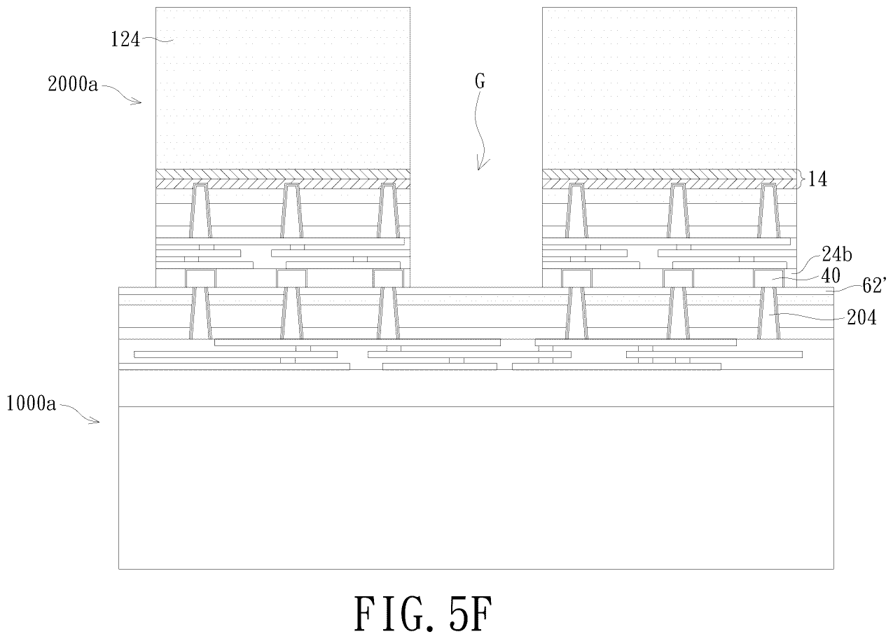

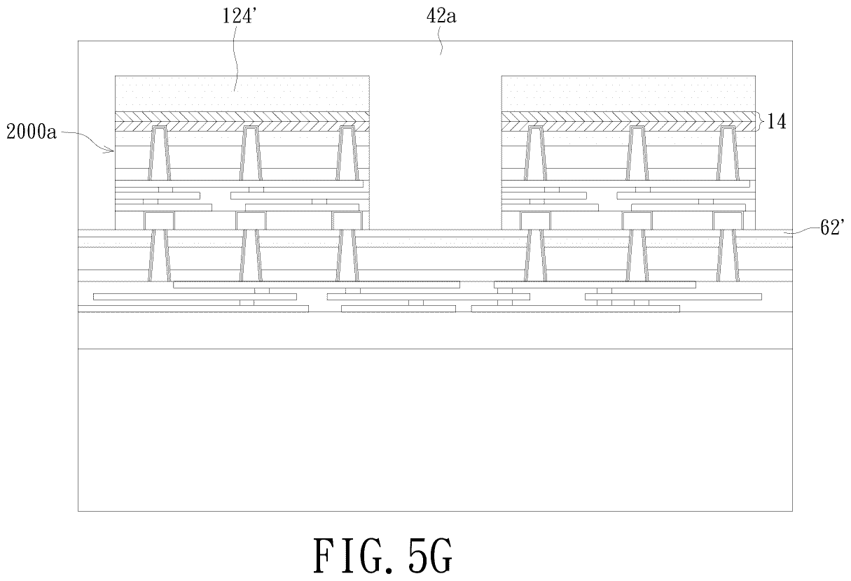

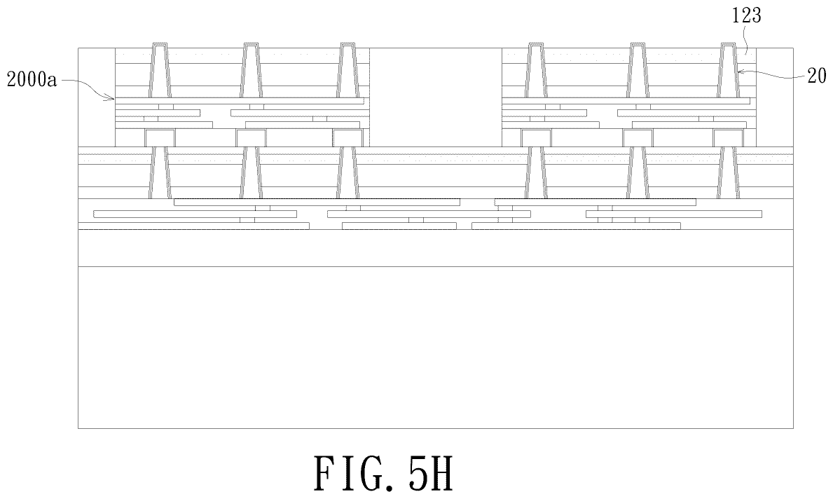

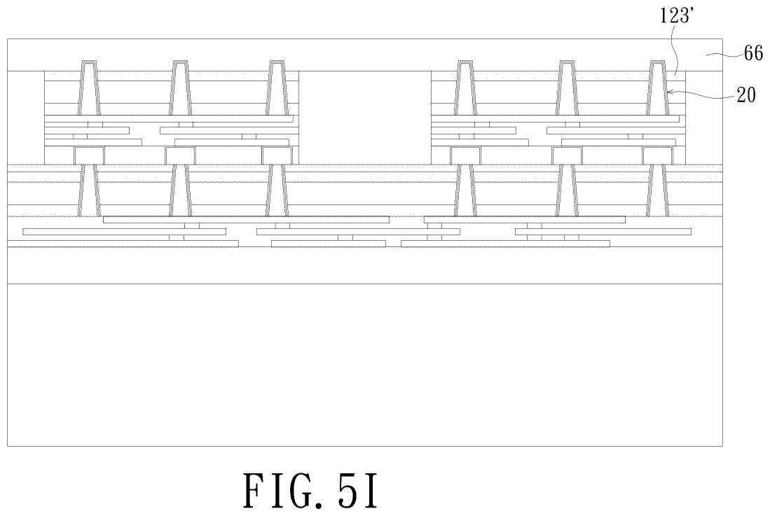

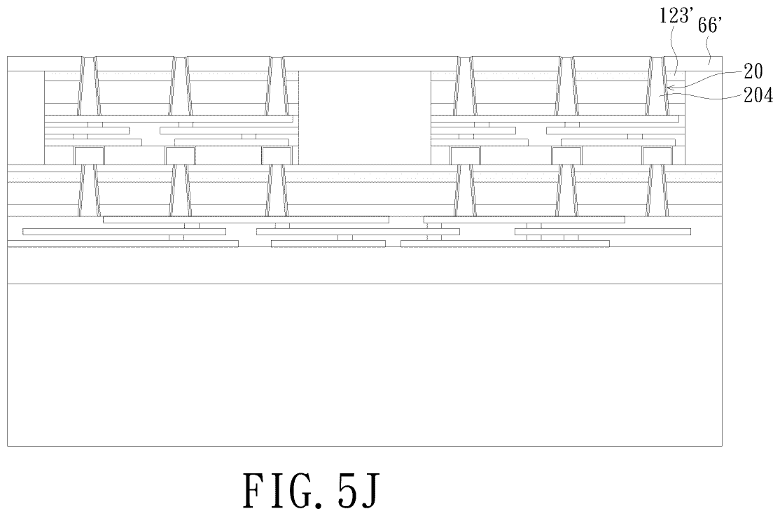

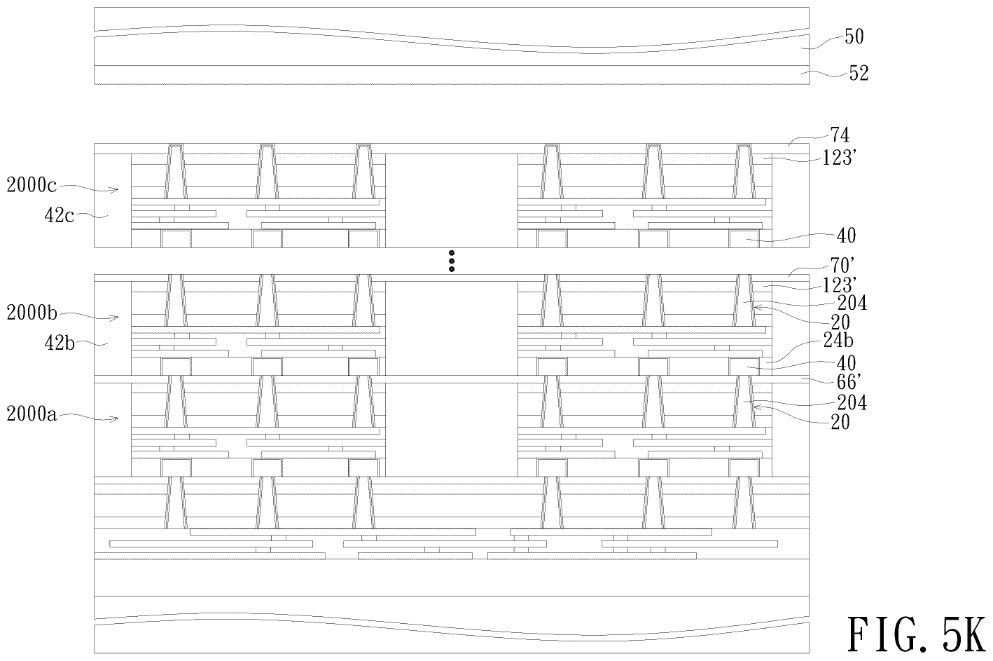

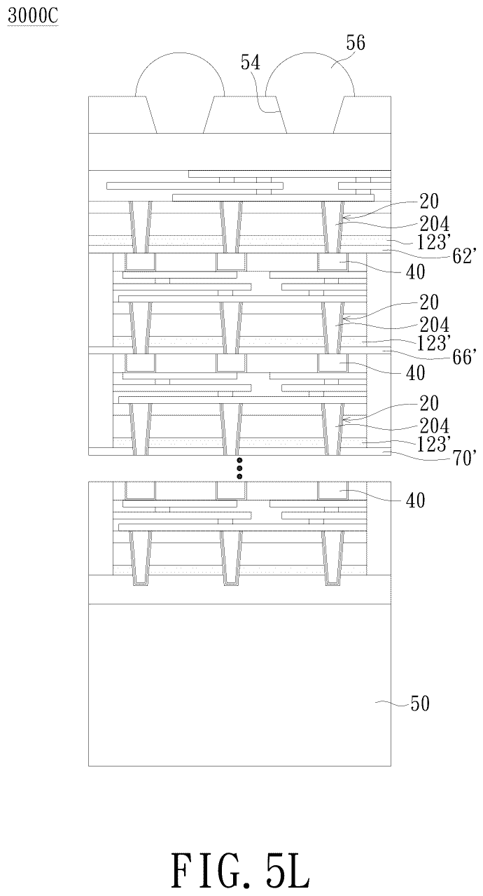

FIG. 5A to FIG. 5L show schematic cross-sectional views of part of stages of a method for manufacturing a semiconductor stack structure with ultra thin die according to a third example of the present invention. The previous stage process of the method for manufacturing a semiconductor stack structure with ultra thin die according to the third example is shown in FIG. 1A to FIG. 1F, and will not be repeated here. As shown in FIG. 5A (corresponding to FIG. 1F), the conductive structures 20 run through the dielectric stop layer 142, the first substrate part 123, the epitaxial layer 16 and the active layer 18 of the first semiconductor wafer 1000a, and are connected to the redistribution layer 22. Next, the dielectric stop layer 142 is removed, as shown in FIG. 5B, to expose the first substrate part 123 and the conductive structures 20. The conductive structures 20 protrude from the first substrate part 123. In an example, the whole dielectric stop layer 142 is removed by a dry etching process, and a height of the conductive structures 20 protruding from the first substrate part 123 is between 50 nm and 500 nm.

Next, optionally, the first substrate part 123 is thinned, as shown in FIG. 5C, and then a first bonding dielectric layer 62 is formed on the thinned first substrate part 123′ to cover the protruding conductive structures 20. In an example, the first bonding dielectric layer 62 is arranged on the thinned first substrate part 123′, for example, by a chemical vapor deposition process, and the thickness of the first bonding dielectric layer 62 needs to be sufficient to cover the protruding conductive structures 20. Then, as shown in FIG. 5D, the first bonding dielectric layer 62 is thinned to expose the conductive materials 204 of the conductive structures 20 from a surface of the first bonding dielectric layer 62′. In an example, based on the consideration of the hybrid bonding technology, part of the first bonding dielectric layer 62′ at a top end of each conductive material 204 and around each conductive structure 20 may optionally have a recess structure 34, and a depth of the recess structure 34 is, for example, between 3 um and 30 um. Additionally, in the subsequent drawings, the recess structure 34 will be omitted.

Next, the first batch of dies 2000a, the second batch of dies 2000b, the third batch of dies 2000c and the subsequent more batches of dies to be stacked are provided. For the manufacturing of each batch of dies, reference may be made to FIG. 2A and FIG. 2B, and details will not be repeated here. As shown in FIG. 5E, the first batch of dies 2000a are flipped such that the first bonding layer 24b of the first batch of dies 2000a is opposite to the first bonding dielectric layer 62′ on the first semiconductor wafer 1000a and the conductive pillars 40 in the first bonding layer 24b of the first batch of dies 2000a respectively correspond to the conductive materials 204 of the first semiconductor wafer 1000a. Next, the first bonding layer 24b of the first batch of dies 2000a and the first bonding dielectric layer 62′ are bonded together by using hybrid bonding technology, as shown in FIG. 5F. The first conductive materials 204 of the first semiconductor wafer 1000a respectively correspond to and are electrically connected to the conductive pillars 40 of the first batch of dies 2000a. FIG. 5F shows an example where there are two first batch of dies 2000a, which is not limited thereto, and there is a gap G between the adjacent first batch of dies.

Then, a back grinding process is performed on the second substrate part 124 of the flipped first batch of dies 2000a to remove a part of the second substrate part 124 from a side of the second substrate part 124 away from the stop layer structure 14 to obtain the remaining (or thinned) second substrate part 124′, as shown in FIG. 5G. Next, a first encapsulant 42a is formed on the first bonding dielectric layer 62′ to cover the first batch of dies 2000a and fill gaps G (denoted in FIG. 5F) between the first batch of dies 2000a. The effects that the remaining second substrate part 124′ can achieve and the method for forming the first encapsulant 42a have been disclosed in the first example and will not be repeated here.

Next, part of the first encapsulant 42a, and the remaining second substrate part 124′ and the whole stop layer structure 14 of the first batch of dies 2000a are removed, as shown in FIG. 5H, to expose the first substrate part 123 of the first batch of dies 2000a and expose the conductive structures 20 protruding from the first substrate part 123. The removing steps have been disclosed in the first example and will not be repeated here. Next, optionally, the first substrate part 123 is thinned, and then a second bonding dielectric layer 66 is formed on the thinned first substrate part 123′ and the conductive structures 20, as shown in FIG. 5I. The second bonding dielectric layer 66 covers the protruding conductive structures 20. Then, the second bonding dielectric layer 66 is thinned, as shown in FIG. 5J, to expose the conductive materials 204 of the conductive structures 20 of the first batch of dies 2000a from a surface of the thinned second bonding dielectric layer 66′ for stacking of the next batch of dies.

As shown in FIG. 5K, the second batch of dies 2000b are flipped such that the first bonding layer 24b of the second batch of dies 2000b is opposite to and is bonded to the thinned second bonding dielectric layer 66′ by using hybrid bonding technology. The conductive materials 204 of the first batch of dies 2000a exposed from the surface of the second bonding dielectric layer 66′ respectively correspond to and are electrically connected to the conductive pillars 40 of the second batch of dies 2000b. Next, a second encapsulant 42b is formed on the second bonding dielectric layer 66′ to cover the second batch of dies 2000b. Then, part of the second encapsulant 42b, and the second substrate part 124 (referring to the first batch of dies 2000a in FIG. 5F), the whole stop layer structure 14 (referring to the first batch of dies 2000a in FIG. 5F) and part of the first substrate part 123 of the second batch of dies 2000b are removed to expose the thinned first substrate part 123′ and the conductive structures 20 of the second batch of dies 2000b. A third bonding dielectric layer 70 is formed on the second encapsulant 42b, and the first substrate part 123′ and the conductive structures 20 of the second batch of dies 2000b, and the conductive materials 204 are exposed by the thinned third bonding dielectric layer 70′.

Additionally, for the next batch of dies (for example, the third batch of dies 2000c), the above steps may be repeated: the third batch of dies are bonded to the thinned third bonding dielectric layer 70′ by using hybrid bonding technology, the conductive pillars 40 of the third batch of dies 2000c respectively correspond to and are electrically connected to the conductive materials 204 of the second batch of dies 2000b, a third encapsulant 42c is formed on the thinned third bonding dielectric layer 70′ to cover the third batch of dies 2000c, the thinned first substrate part 123′ of the third batch of dies 2000c is exposed through removing and other steps, a fourth bonding dielectric layer 74 is formed on the thinned first substrate part 123′ of the third batch of dies 2000c, thinning the fourth bonding dielectric layer 74 of the third batch of dies 2000c to expose the conductive materials 204, and so on. These steps are repeated many times to complete the stacking of a predetermined number of layers of dies. Then, a dummy carrier board 50 is provided such that the fourth bonding layer 52 of the dummy carrier board 50 is bonded to the fourth bonding dielectric layer 74 of the top dies (for example, the third batch of dies 2000c) farthest from the carrier board 30.

Continuing with the above description, after the bonding to the dummy carrier board 50, the subsequent processes of removing of the carrier board 30, forming of the slots 54, arranging of the solder balls 56 and die sawing are further performed, which have been disclosed in the first example and will not be repeated here. FIG. 5L shows the semiconductor stack structure with ultra thin die 3000C after die sawing, which is different from the semiconductor stack structure with ultra thin die 3000A shown in FIG. 1R in the first example mainly in that: the whole stop layer structure 14 (including the dielectric stop layer 142) of the semiconductor stack structure with ultra thin die 3000C is removed, the bonding dielectric layer (for example, the first bonding dielectric layer 62/second bonding dielectric layer 66/third bonding dielectric layer 70) is further formed on the first substrate part 123′, and the conductive materials 204 of the conductive structures 20 are exposed by the thinning of the bonding dielectric layer, so that the first bonding layer 24b of each batch of dies is hybrid-bonded to the first bonding dielectric layer 62′/second bonding dielectric layer 66′/third bonding dielectric layer 70′, rather than that the first bonding layer 24b of each batch of dies is directly hybrid-bonded to the exposed stop layer structure (for example, the dielectric stop layer 142′) as shown in the semiconductor stack structure with ultra thin die 3000A in FIG. 1R.

Additionally, the semiconductor stack structure with ultra thin die 3000C is different from the semiconductor stack structure with ultra thin die 3000B in FIG. 4I mainly in that: the conductive pillars 40 of each batch of dies of the semiconductor stack structure with ultra thin die 3000C are in contact and are electrically connected with the conductive materials 204 of the conductive structures 20 of the previous batch of dies (or the first semiconductor wafer), rather than that the conductive pillars 40 of each batch of dies as shown in the semiconductor stack structure with ultra thin die 3000B are in contact and electrically connected with the first conductive blocks 64/second conductive blocks 68/third conductive blocks 72.

Based on the above, the semiconductor stack structure with ultra thin die according to the example of the present invention may be applied to logic/memory or passive die stacking. By continuously stacking the dies face to face, a multilayer 3D chip structure can be formed. The stop layer structure in each batch of dies can form a robust etch stop mechanism, so wafer warpage and total thickness variation (TTV) can be avoided. Additionally, since the second substrate part, the deep dielectric stop layer and the dielectric stop layer have different etch selectivities, when the thinning process of each batch of dies is continuously performed through wet etching, dry etching and chemical mechanical polishing processes, the process window can be increased, and the stability of the semiconductor stack structure with ultra thin die can be improved. Since the overall thickness of each layer of dies is not greater than 12 um and the total thickness of the chip is limited to below 700 um, more than 60 layers of thinned dies can be stacked, so that the semiconductor stack structure with ultra thin die according to the example of the present invention can meet the requirement of high integration and speed, and has better electrical properties and efficiency.

Although the present invention has been disclosed with the above examples, it is not intended to limit the present invention. Any person of ordinary skill in the art to which the present invention belongs can make some changes and modifications without departing from the spirit and scope of the present invention. Therefore, the protection scope of the present invention shall be defined by the appended claims.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a semiconductor stack structure with ultra thin die, comprising:
manufacturing a plurality of semiconductor wafers, wherein the manufacturing of each of the semiconductor wafers comprises:
providing a semiconductor substrate having an active surface and a back surface opposite to each other;
forming a stop layer structure in the semiconductor substrate to divide the semiconductor substrate into a first substrate part and a second substrate part, wherein the first substrate part is located between the stop layer structure and the active surface, the second substrate part is located between the stop layer structure and the back surface, the stop layer structure comprises at least a dielectric stop layer, and the manufacturing of the dielectric stop layer comprises performing an ion implantation process at a depth of the semiconductor substrate and then performing a high-temperature treatment process such that the dielectric stop layer is formed in an area implanted by the ion implantation process;
sequentially forming an epitaxial layer and an active layer on the active surface, and forming a plurality of conductive structures passing through the active layer, the epitaxial layer and the first substrate part, the conductive structures being connected to the dielectric stop layer;
forming a redistribution layer on the active layer, the redistribution layer being electrically connected to the conductive structures; and
arranging a first bonding layer on the redistribution layer;
providing a carrier board, and forming a second bonding layer on the carrier board;
selecting one of the semiconductor wafers as a first semiconductor wafer, and flipping the first semiconductor wafer such that the first bonding layer of the first semiconductor wafer and the second bonding layer are bonded together;
removing the second substrate part and part of the stop layer structure to expose the dielectric stop layer and the conductive structures of the first semiconductor wafer;
selecting another one of the semiconductor wafers as a second semiconductor wafer, and arranging a plurality of conductive pillars on the first bonding layer of the second semiconductor wafer, the conductive pillars being electrically connected to the redistribution layer;
performing die sawing on the second semiconductor wafer formed with the conductive pillars as a first batch of dies and a second batch of dies to be stacked;
flipping the first batch of dies such that the first bonding layer of the first batch of dies is opposite to and is bonded to the dielectric stop layer of the first semiconductor wafer by using hybrid bonding technology, wherein the conductive structures of the first semiconductor wafer respectively correspond to and are electrically connected to the conductive pillars of the first batch of dies;
forming a first encapsulant on the dielectric stop layer of the first semiconductor wafer to cover the first batch of dies and fill between the first batch of dies; and
removing part of the first encapsulant, and removing the second substrate part and part of the stop layer structure of the first batch of dies to expose the dielectric stop layer and the conductive structures of the first batch of dies.

2. The method for manufacturing a semiconductor stack structure with ultra thin die according to claim 1, wherein after exposing the dielectric stop layer and the conductive structures of the first batch of dies, the method further comprises:
flipping the second batch of dies such that the first bonding layer of the second batch of dies is opposite to and is bonded to the dielectric stop layer of the first batch of dies by using hybrid bonding technology, wherein the conductive structures of the first batch of dies respectively correspond to and are electrically connected to the conductive pillars of the second batch of dies;
forming a second encapsulant on the dielectric stop layer of the first batch of dies to cover the second batch of dies and fill between the second batch of dies; and
removing part of the second encapsulant, and removing the second substrate part and part of the stop layer structure of the second batch of dies to expose the dielectric stop layer and the conductive structures of the second batch of dies.

3. The method for manufacturing a semiconductor stack structure with ultra thin die according to claim 2, further comprising:
forming a third bonding layer on the dielectric stop layer of the second batch of dies and the second encapsulant;
providing a dummy carrier board, forming a fourth bonding layer on the dummy carrier board, and bonding the fourth bonding layer and the third bonding layer together;
removing the carrier board, and exposing the second bonding layer;
forming a plurality of slots in the second bonding layer and the first bonding layer of the first semiconductor wafer to expose the redistribution layer of the first semiconductor wafer;
arranging a plurality of solder balls in the slots respectively such that the solder balls are electrically connected to the redistribution layer; and
performing die sawing corresponding to positions of the second batch of dies.

4. The method for manufacturing a semiconductor stack structure with ultra thin die according to claim 1, wherein a method for manufacturing the stop layer structure comprises:
performing a first ion implantation process at a first depth of the semiconductor substrate;
performing a second ion implantation process at a second depth of the semiconductor substrate, the second depth being different from the first depth, and elements used in the first ion implantation process being different from elements used in the second ion implantation process; and
performing a high-temperature treatment process such that a deep dielectric stop layer is formed in an area implanted by the first ion implantation process and the dielectric stop layer is formed in an area implanted by the second ion implantation process, the dielectric stop layer being between the deep dielectric stop layer and the active surface.

5. The method for manufacturing a semiconductor stack structure with ultra thin die according to claim 4, wherein the elements used in the first ion implantation process and the elements used in the second ion implantation process are selected from boron, carbon, nitrogen, fluorine, phosphorus, argon and arsenic.

6. The method for manufacturing a semiconductor stack structure with ultra thin die according to claim 4, wherein the steps of removing the second substrate part and part of the stop layer structure comprise:
performing a back grinding process to remove a part of the second substrate part from a side of the second substrate part away from the stop layer structure;
removing another part of the second substrate part by a wet etching process, wherein an etch selectivity of the deep dielectric stop layer to the second substrate part is between 1/10 and 1/300;
removing the deep dielectric stop layer by a dry etching process, wherein an etch selectivity of the dielectric stop layer to the deep dielectric stop layer is between ⅕ and 1/100; and
performing a polishing process to remove part of the dielectric stop layer and expose the conductive structures.

7. The method for manufacturing a semiconductor stack structure with ultra thin die according to claim 1, wherein the epitaxial layer is deposited on the active surface by a metal-organic chemical vapor deposition process, and at least one active component further forms the epitaxial layer.

8. The method for manufacturing a semiconductor stack structure with ultra thin die according to claim 1, wherein a method for manufacturing the conductive structures comprises:
forming a plurality of through holes passing through part of the dielectric stop layer, the first substrate part, the epitaxial layer and the active layer;
sequentially conformally forming an insulating layer and a barrier layer on side walls and bottom walls of the through holes; and
arranging conductive materials in the through holes.

9. The method for manufacturing a semiconductor stack structure with ultra thin die according to claim 1, wherein the first bonding layer and the second bonding layer are bonded together by a fusion bonding process.

10. The method for manufacturing a semiconductor stack structure with ultra thin die according to claim 1, wherein before forming the first encapsulant to cover the first batch of dies, a back grinding process is performed on the second substrate part of the first batch of dies to remove a part of the second substrate part from a side of the second substrate part away from the stop layer structure.

11. The method for manufacturing a semiconductor stack structure with ultra thin die according to claim 10, wherein after forming the first encapsulant to cover the first batch of dies, the steps of removing part of the first encapsulant, and removing the second substrate part and part of the stop layer structure of the first batch of dies comprise:
polishing part of the first encapsulant on the second substrate part by a chemical mechanical polishing process;
removing another part of the second substrate part by a wet etching process;
removing part of the stop layer structure by a dry etching process to expose the dielectric stop layer of the first batch of dies; and
polishing part of the dielectric stop layer by a chemical mechanical polishing process to expose the conductive structures.

12. A method for manufacturing a semiconductor stack structure with ultra thin die, comprising:
manufacturing a plurality of semiconductor wafers, wherein the manufacturing of each of the semiconductor wafers comprises:
providing a semiconductor substrate having an active surface and a back surface opposite to each other;
forming a stop layer structure in the semiconductor substrate to divide the semiconductor substrate into a first substrate part and a second substrate part, wherein the first substrate part is located between the stop layer structure and the active surface, the second substrate part is located between the stop layer structure and the back surface, the stop layer structure comprises at least a dielectric stop layer, and the manufacturing of the dielectric stop layer comprises performing an ion implantation process at a depth of the semiconductor substrate and then performing a high-temperature treatment process such that the dielectric stop layer is formed in an area implanted by the ion implantation process;
sequentially forming an epitaxial layer and an active layer on the active surface, and forming a plurality of conductive structures passing through the active layer, the epitaxial layer and the first substrate part, the conductive structures being connected to the dielectric stop layer;
forming a redistribution layer on the active layer, the redistribution layer being electrically connected to the conductive structures; and
arranging a first bonding layer on the redistribution layer;
providing a carrier board, and forming a second bonding layer on the carrier board;
selecting one of the semiconductor wafers as a first semiconductor wafer, and flipping the first semiconductor wafer such that the first bonding layer of the first semiconductor wafer and the second bonding layer are bonded together;
removing the second substrate part and part of the stop layer structure to expose the dielectric stop layer and the conductive structures of the first semiconductor wafer;
forming a first bonding dielectric layer on the dielectric stop layer and the conductive structures of the first semiconductor wafer, a plurality of first conductive blocks passing through the first bonding dielectric layer, and the first conductive blocks being respectively electrically connected to the conductive structures;
selecting another one of the semiconductor wafers as a second semiconductor wafer, and arranging a plurality of conductive pillars on the first bonding layer of the second semiconductor wafer, the conductive pillars being electrically connected to the redistribution layer;
performing die sawing on the second semiconductor wafer formed with the conductive pillars as a first batch of dies and a second batch of dies to be stacked;
flipping the first batch of dies such that the first bonding layer of the first batch of dies is opposite to and is bonded to the first bonding dielectric layer by using hybrid bonding technology, wherein the first conductive blocks of the first bonding dielectric layer respectively correspond to and are electrically connected to the conductive pillars of the first batch of dies;
forming a first encapsulant on the first bonding dielectric layer of the first semiconductor wafer to cover the first batch of dies and fill between the first batch of dies; and
removing part of the first encapsulant, and removing the second substrate part and part of the stop layer structure of the first batch of dies to expose the dielectric stop layer and the conductive structures of the first batch of dies.

13. The method for manufacturing a semiconductor stack structure with ultra thin die according to claim 12, wherein after exposing the dielectric stop layer and the conductive structures of the first batch of dies, the method further comprises:
forming a second bonding dielectric layer on the first encapsulant, and the dielectric stop layer and the conductive structures of the first batch of dies, a plurality of second conductive blocks passing through the second bonding dielectric layer, and the second conductive blocks being respectively electrically connected to the conductive structures;
flipping the second batch of dies such that the first bonding layer of the second batch of dies is opposite to and is bonded to the second bonding dielectric layer by using hybrid bonding technology, wherein the second conductive blocks respectively correspond to and are electrically connected to the conductive pillars of the second batch of dies;
forming a second encapsulant on the second bonding dielectric layer to cover the second batch of dies and fill between the second batch of dies;
and removing part of the second encapsulant, and removing the second substrate part and part of the stop layer structure of the second batch of dies to expose the dielectric stop layer and the conductive structures of the second batch of dies.

14. The method for manufacturing a semiconductor stack structure with ultra thin die according to claim 13, further comprising:
forming a third bonding layer on the dielectric stop layer of the second batch of dies and the second encapsulant;
providing a dummy carrier board, forming a fourth bonding layer on the dummy carrier board, and bonding the fourth bonding layer and the third bonding layer together;
removing the carrier board, and exposing the second bonding layer;
forming a plurality of slots in the second bonding layer and the first bonding layer of the first semiconductor wafer to expose the redistribution layer of the first semiconductor wafer;
arranging a plurality of solder balls in the slots respectively such that the solder balls are electrically connected to the redistribution layer; and
performing die sawing corresponding to positions of the first batch of dies or the second batch of dies.

15. A method for manufacturing a semiconductor stack structure with ultra thin die, comprising:
manufacturing a plurality of semiconductor wafers, wherein the manufacturing of each of the semiconductor wafers comprises:
providing a semiconductor substrate having an active surface and a back surface opposite to each other;
forming a stop layer structure in the semiconductor substrate to divide the semiconductor substrate into a first substrate part and a second substrate part, wherein the first substrate part is located between the stop layer structure and the active surface, the second substrate part is located between the stop layer structure and the back surface, the stop layer structure comprises at least a dielectric stop layer, and the manufacturing of the dielectric stop layer comprises performing an ion implantation process at a depth of the semiconductor substrate and then performing a high-temperature treatment process such that the dielectric stop layer is formed in an area implanted by the ion implantation process;
sequentially forming an epitaxial layer and an active layer on the active surface, and forming a plurality of conductive structures passing through the active layer, the epitaxial layer and the first substrate part, the conductive structures being connected to the dielectric stop layer;
forming a redistribution layer on the active layer, the redistribution layer being electrically connected to the conductive structures; and
arranging a first bonding layer on the redistribution layer;
providing a carrier board, and forming a second bonding layer on the carrier board;
selecting one of the semiconductor wafers as a first semiconductor wafer, and flipping the first semiconductor wafer such that the first bonding layer of the first semiconductor wafer and the second bonding layer are bonded together;
removing the second substrate part and the stop layer structure of the first semiconductor wafer to expose the first substrate part and the conductive structures of the first semiconductor wafer, wherein the conductive structures protrude from the first substrate part;
forming a first bonding dielectric layer on the first substrate part and the conductive structures of the first semiconductor wafer;
thinning the first bonding dielectric layer to expose the conductive structures of the first semiconductor wafer from a surface of the first bonding dielectric layer;
selecting another one of the semiconductor wafers as a second semiconductor wafer, and arranging a plurality of conductive pillars on the first bonding layer of the second semiconductor wafer, the conductive pillars being electrically connected to the redistribution layer;
performing die sawing on the second semiconductor wafer formed with the conductive pillars as a first batch of dies and a second batch of dies to be stacked;
flipping the first batch of dies such that the first bonding layer of the first batch of dies is opposite to and is bonded to the first bonding dielectric layer by using hybrid bonding technology, wherein the conductive structures exposed from the surface of the first bonding dielectric layer respectively correspond to and are electrically connected to the conductive pillars of the first batch of dies;
forming a first encapsulant on the first bonding dielectric layer to cover the first batch of dies and fill between the first batch of dies; and
removing part of the first encapsulant, and removing the second substrate part and the stop layer structure of the first batch of dies to expose the first substrate part and the conductive structures of the conductive structure, wherein the conductive structures protrude from the first substrate part;
forming a second bonding dielectric layer on the first substrate part and the conductive structures of the first batch of dies; and
thinning the second bonding dielectric layer to expose the conductive structures of the first batch of dies from a surface of the second bonding dielectric layer.

16. The method for manufacturing a semiconductor stack structure with ultra thin die according to claim 15, wherein after exposing the conductive structures of the first batch of dies from the surface of the second bonding dielectric layer, the method further comprises:
flipping the second batch of dies such that the first bonding layer of the second batch of dies is opposite to and is bonded to the second bonding dielectric layer by using hybrid bonding technology, wherein the conductive structures of the first batch of dies respectively correspond to and are electrically connected to the conductive pillars of the second batch of dies;
forming a second encapsulant on the second bonding dielectric layer to cover the second batch of dies and fill between the second batch of dies; and
removing part of the second encapsulant, and removing the second substrate part and the stop layer structure of the second batch of dies to expose the first substrate part and the conductive structures of the second batch of dies, wherein the conductive structures protrude from the first substrate part;
forming a third bonding dielectric layer on the first substrate part and the conductive structures of the second batch of dies; and
thinning the third bonding dielectric layer to expose the conductive structures of the second batch of dies from a surface of the third bonding dielectric layer.

17. The method for manufacturing a semiconductor stack structure with ultra thin die according to claim 16, further comprising:
providing a dummy carrier board, forming a fourth bonding layer on the dummy carrier board, and bonding the fourth bonding layer and the third bonding dielectric layer together;
removing the carrier board, and exposing the second bonding layer;
forming a plurality of slots in the second bonding layer and the first bonding layer of the first semiconductor wafer to expose the redistribution layer of the first semiconductor wafer;
arranging a plurality of solder balls in the slots respectively such that the solder balls are electrically connected to the redistribution layer; and
performing die sawing corresponding to positions of the first batch of dies or the second batch of dies.

18. The method for manufacturing a semiconductor stack structure with ultra thin die according to claim 15, wherein before forming the first bonding dielectric layer, the method further comprises thinning the first substrate part of the first semiconductor wafer; and before forming the second bonding dielectric layer, the method further comprises thinning the first substrate part of the first batch of dies.
